(19) United States
(12) Patent Application Publication
(10) Pub. No.: US 2026/0353963 A1
(43) Pub. Date: Nov. 5, 2026

(54) ARRAY SUBSTRATE AND DISPLAY PANEL

(71) Applicant: Beijing Visionox Technology Co., Ltd., Beijing (CN)

(72) Inventors: Enqing GUO, Beijing (CN); Cuili GAI, Beijing (CN); Lei MI, Beijing (CN); Jianjun LU, Beijing (CN); Shuang GUO, Beijing (CN); Xiaoyang JIN, Beijing (CN); Yun CHENG, Beijing (CN)

(73) Assignee: Beijing Visionox Technology Co., Ltd., Beijing (CN)

(21) Appl. No.: 19/728,248

(22) Filed: Jul. 1, 2026

(30) Foreign Application Priority Data
Nov. 24, 2025 (CN) 202511735816.3

(51) Int. Cl. H10K 59/131; H10K 59/121

(52) U.S. Cl. CPC H10K 59/1315; H10K 59/1213; H10K 59/1216

(57) ABSTRACT

The present application discloses an array substrate and a display panel. The array substrate includes: a pixel circuit including a first capacitor, a second capacitor, a driving transistor, and at least two scan lines; the pixel circuit includes a first-type transistor and a second-type transistor; along a second direction, an orthographic projection of the first capacitor on the substrate, an orthographic projection of the second capacitor on the substrate, and an orthographic projection of the driving transistor on the substrate are located between orthographic projections on the substrate of any two scan lines respectively connected to the first-type transistor and the second-type transistor, and the first capacitor and the second capacitor are arranged along the second direction; and the second direction intersects a first direction.

### CROSS-REFERENCE TO RELATED APPLICATIONS

The present application claims priority to the Chinese Patent Application 202511735816.3, filed on Nov. 24, 2025, and the entire contents of the above application are hereby incorporated by reference in its entirety.

### FIELD

The present application relates to the field of display technology, and in particular, to an array substrate and a display panel.

### BACKGROUND

Flat panel display devices based on technologies such as Organic Light Emitting Display (OLED) and Light Emitting Diode (LED) are widely used in various consumer electronic products such as mobile phones, televisions, notebook computers, and desktop computers due to their advantages of high image quality, low power consumption, thin profile, and wide application range, and have become mainstream in display devices.

However, the performance of current OLED display panels needs to be improved.

### SUMMARY

The present application provides an array substrate and a display panel to improve the performance of the display panel.

According to one aspect of the present application, an array substrate is provided. The array substrate includes:
a substrate;
at least one active layer and a plurality of conductive layers stacked on one side of the substrate, the at least one active layer and the plurality of conductive layers forming at least one pixel circuit, the pixel circuit including a first capacitor, a second capacitor, a driving transistor, and a plurality of switching transistors;
in one embodiment, the plurality of conductive layers includes at least two scan lines, the scan lines extending along a first direction, the driving transistor and the plurality of switching transistors being each connected to one of the scan lines;
the plurality of switching transistors include a first-type transistor and a second-type transistor; along a second direction, an orthographic projection of the first capacitor on the substrate, an orthographic projection of the second capacitor on the substrate, and an orthographic projection of the driving transistor on the substrate are located between orthographic projections on the substrate of any two of the scan lines, the two scan lines being respectively connected to the first-type transistor and the second-type transistor, and the first capacitor and the second capacitor are arranged along the second direction, and the second direction intersects the first direction.

According to another aspect of the present application, an array substrate is provided. The array substrate includes:
a substrate;
a first conductive layer, a third conductive layer, and a fourth conductive layer sequentially stacked in a direction away from the substrate;
a first scan line, located in the fourth conductive layer;
a third scan line, located in the first conductive layer and the fourth conductive layer;
a fourth scan line, located in the first conductive layer, the third conductive layer, and the fourth conductive layer;
in one embodiment, orthographic projections of the first scan line, the third scan line, and the fourth scan line on the substrate all extend along a first direction and are spaced apart along a second direction, the first direction intersects the second direction.

According to another aspect of the present application, a display panel is provided. The display panel includes the array substrate according to any embodiment of the present application.

According to the embodiments of the present application, the pixel circuit of the array substrate includes a first capacitor, a second capacitor, and a driving transistor. Along the second direction, the orthographic projection of the first capacitor on the substrate, the orthographic projection of the second capacitor on the substrate, and the orthographic projection of the driving transistor on the substrate are located between the orthographic projections on the substrate of any two scan lines respectively connected to the first-type transistor and the second-type transistor, and the first capacitor and the second capacitor are arranged along the second direction. This arrangement separates the two scan lines respectively connected to the first-type transistor and the second-type transistor by the first capacitor, the driving transistor, and the second capacitor, resulting in reduced crosstalk between the two scan lines respectively connected to the first-type transistor and the second-type transistor. This is beneficial for improving the reliability of signals transmitted on the scan lines and enhances the performance of the display panel.

The content described in this section is not intended to identify key or essential features of the embodiments of the present application, nor is it intended to limit the scope of the present application. Other features of the present application will become apparent from the following description.

### BRIEF DESCRIPTION OF THE DRAWINGS

To clearly illustrate the embodiments, the drawings required for description are introduced below. The drawings depict some embodiments, and other drawings can be derived in the art without undue experimentation.

FIG. 1 is a schematic structural diagram of an array substrate provided by an embodiment of the present application;

FIG. 2 is a schematic structural diagram of a pixel circuit provided by an embodiment of the present application;

FIG. 3 is a cross-sectional view taken along line a1-a2 of FIG. 1;

FIG. 4 is a schematic structural diagram of another array substrate provided by an embodiment of the present application;

FIG. 5 is a schematic structural diagram of yet another array substrate provided by an embodiment of the present application;

FIG. 6 is a cross-sectional view taken along line b1-b2 of FIG. 5;

FIG. 7 is a schematic structural diagram of yet another array substrate provided by an embodiment of the present application;

FIG. 8 is a schematic view taken along line e1-e2 of FIG. 7;

FIG. 9 is a schematic structural diagram of yet another array substrate provided by an embodiment of the present application;

FIG. 10 is a schematic structural diagram of an array substrate provided by an embodiment of the present application;

FIG. 11 is a schematic structural diagram of yet another array substrate provided by an embodiment of the present application;

FIG. 12 is a cross-sectional view taken along line f1-f2 of FIG. 11;

FIG. 13 is a cross-sectional view taken along line f3-f4 of FIG. 11;

FIG. 14 is a schematic structural diagram of yet another array substrate provided by an embodiment of the present application;

FIG. 15 is a cross-sectional view taken along line h1-h2 of FIG. 14;

FIG. 16 is a schematic structural diagram of yet another array substrate provided by an embodiment of the present application;

FIG. 17 is a timing diagram of a pixel circuit provided by an embodiment of the present application;

FIG. 18 is a schematic structural diagram of a display panel provided by an embodiment of the present application.

### DETAILED DESCRIPTION OF THE EMBODIMENTS

To enable those to better understand the solutions of the present application, the embodiments of the present application will be clearly and completely described below with reference to the accompanying drawings in the embodiments of the present application. In one embodiment, the described embodiments are only a part of the embodiments of the present application, rather than all of them. All other embodiments that can be derived in the art from the embodiments of the present application without undue experimentation shall fall within the scope of the present application.

The terms “first”, “second”, etc. in the specification and claims of the present application and the above drawings are used to distinguish similar objects, and are not necessarily used to describe a specific order or sequence. The data used in one embodiment, may be interchanged under appropriate circumstances, and the embodiments of the present application described herein can be implemented in an order other than those illustrated or described herein. In addition, the terms “comprise” and “have” and any variations thereof are intended to cover non-exclusive inclusion. For example, a process, method, system, product, or device that includes a series of steps or units is not necessarily limited to those clearly listed steps or units, but may include other steps or units that are not clearly listed or are inherent to these processes, methods, products, or devices.

As mentioned in the background art, existing display panels have the problem that their performance needs to be improved. Through research by the inventors, it is found that the cause of this problem lies in that the display panel includes a pixel circuit, which can generate a driving current to drive a light-emitting device in the display panel to emit light. The pixel circuit includes thin-film transistors. Polycrystalline silicon transistors have the advantages of stable characteristics, high mobility, and mature processes. Oxide transistors have the advantages of small leakage current and high uniformity. Therefore, in related technologies, a portion of the transistors in the pixel circuit are polycrystalline silicon transistors, and another portion are oxide transistors. However, in display panels of related technologies, the spacing between scan lines of oxide transistors and polycrystalline silicon transistors is relatively close, causing existing display panels including oxide transistors and polycrystalline silicon transistors to have a problem of relatively large crosstalk, resulting in poor performance of the display panel.

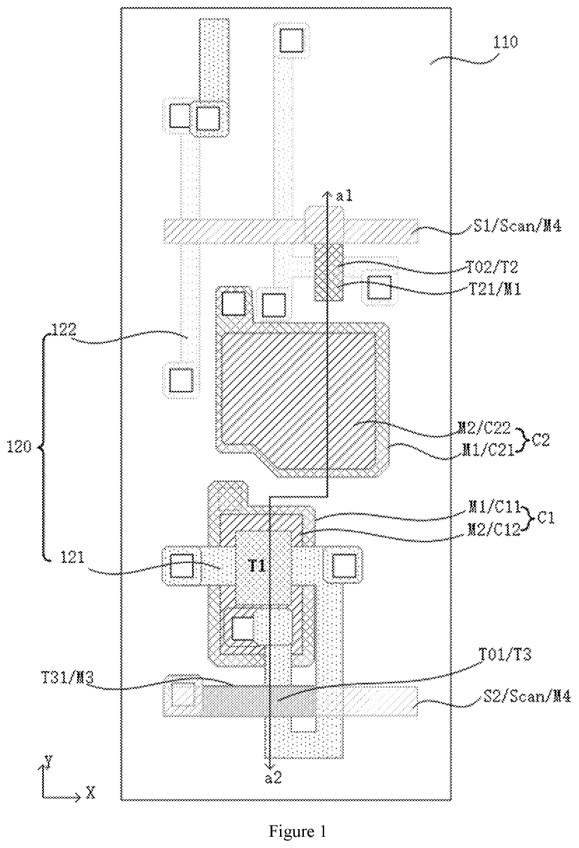

To address the above problem, an embodiment of the present application provides an array substrate. FIG. 1 is a schematic structural diagram of an array substrate provided by an embodiment of the present application. Referring to FIG. 1, the array substrate includes:
a substrate 110;
at least one active layer 120 and a plurality of conductive layers stacked on one side of the substrate 110, and the two types of active layer 120 and the plurality of conductive layers form at least one pixel circuit 210, and the pixel circuit 210 includes a first capacitor C1, a second capacitor C2, a driving transistor T1, and a plurality of switching transistors;
in one embodiment, the plurality of conductive layers includes at least two scan lines Scan, and the scan lines Scan extend along a first direction X, the driving transistor T1 and the plurality of switching transistors being each connected to one of the scan lines; the plurality of switching transistors include a first-type transistor T01 and a second-type transistor T02; along a second direction Y, an orthographic projection of the first capacitor C1 on the substrate 110, an orthographic projection of the second capacitor C2 on the substrate 110, and an orthographic projection of the driving transistor T1 on the substrate 110 are located between orthographic projections on the substrate 110 of any two scan lines, the two scan lines being respectively connected to the first-type transistor T01 and the second-type transistor T02, and the first capacitor C1 and the second capacitor C2 are arranged along the second direction Y; and the second direction Y intersects the first direction X.

In some embodiments the substrate 110 has functions of support, protection, and buffering. The substrate 110 may be a flexible substrate, such as a polyimide (PI) substrate, etc., or the substrate 110 may be a rigid substrate, such as a glass substrate, etc., which is not limited herein.

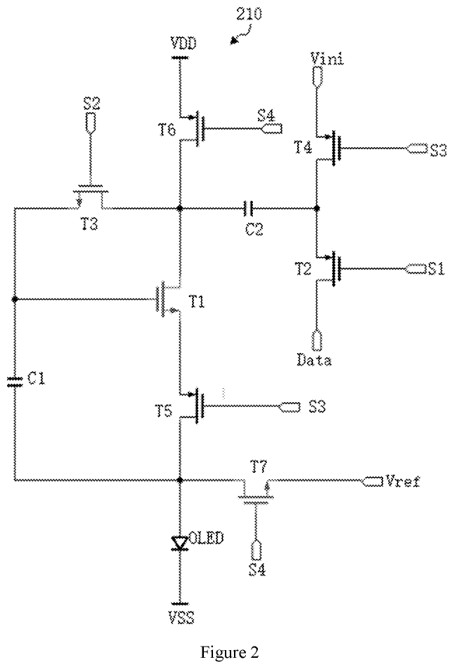

The pixel circuit 210 can generate a driving current to drive a light-emitting device in a display panel formed by the array substrate to emit light. Exemplarily, FIG. 2 is a schematic structural diagram of a pixel circuit provided by an embodiment of the present application. As shown in FIG. 2, the pixel circuit 210 includes a first capacitor C1, a second capacitor C2, and a driving transistor T1. The driving transistor T1 can generate a driving current to drive the light-emitting device to emit light. The first capacitor C1 and the second capacitor C2 have a coupling function and can couple and transmit voltages.

The types of the first-type transistor T01 and the second-type transistor T02 are different. For example, one of the first-type transistor T01 and the second-type transistor T02 is an N-type transistor, and the other is a P-type transistor, which is not limited herein.

In some embodiments, by arranging along the second direction Y, the orthographic projection of the first capacitor C1 on the substrate 110, the orthographic projection of the second capacitor C2 on the substrate 110, and the orthographic projection of the driving transistor T1 on the substrate 110 to be located between the orthographic projections on the substrate 110 of any two scan lines, two scan lines respectively connected to the first-type transistor T01 and the second-type transistor T02, and arranging the first capacitor C1 and the second capacitor C2 along the second direction Y, the two scan lines Scan respectively connected to the first-type transistor T01 and the second-type transistor T02 are separated by the first capacitor C1, the driving transistor T1, and the second capacitor C2. That is, the interval between the two scan lines Scan respectively connected to the first-type transistor T01 and the second-type transistor T02 is relatively large, resulting in less crosstalk between the two scan lines Scan respectively connected to the first-type transistor T01 and the second-type transistor T02. This is beneficial for improving the reliability of signals transmitted on the scan lines Scan and enhances the performance of the display panel.

In some embodiments, the pixel circuit of the array substrate includes a first capacitor, a second capacitor, and a driving transistor. Along the second direction, the orthographic projection of the first capacitor on the substrate, the orthographic projection of the second capacitor on the substrate, and the orthographic projection of the driving transistor on the substrate are located between the orthographic projections on the substrate of any two scan lines respectively connected to the first-type transistor and the second-type transistor. The first capacitor and the second capacitor are arranged along the second direction, causing the two scan lines respectively connected to the first-type transistor and the second-type transistor to be separated by the first capacitor, the driving transistor, and the second capacitor. This results in less crosstalk between the two scan lines respectively connected to the first-type transistor and the second-type transistor, which is beneficial for improving the reliability of signals transmitted on the scan lines and enhances the performance of the display panel.

In some embodiments, continuing to refer to FIG. 1, at least two scan lines include a first scan line S1 and a second scan line S2.

The plurality of switching transistors further includes a data writing transistor T2 and a threshold compensation transistor T3.

The first scan line S1 is connected to the gate T21 of the data writing transistor T2, and the second scan line S2 is connected to the gate of the threshold compensation transistor T3.

Along the second direction Y, the orthographic projection of the first capacitor C1 on the substrate 110, the orthographic projection of the second capacitor C2 on the substrate 110, and the orthographic projection of the driving transistor T1 on the substrate 110 are all located within a region defined between the orthographic projection of the first scan line S1 on the substrate 110 and the orthographic projection of the second scan line S2 on the substrate 110.

The threshold compensation transistor T3 is the first-type transistor T01, and the data writing transistor T2 is the second-type transistor T02.

The channel types of the first-type transistor T01 and the second-type transistor T02 are different.

In some embodiments, one of the first-type transistor T01 and the second-type transistor T02 is an N-type transistor, and the other is a P-type transistor.

As shown in FIG. 2, the data writing transistor T2 can be connected to a data line Data. When the data writing transistor T2 is turned on, it transmits the data voltage on the data line Data, enabling the driving transistor T1 to generate a driving current based on the data voltage. When the threshold compensation transistor T3 is turned on, it can transmit a voltage related to the threshold voltage of the driving transistor T1 to the gate of the driving transistor T1. The gate-source voltage difference of the driving transistor T1 is related to the threshold voltage of the driving transistor T1, and the driving current generated by the driving transistor T1 is related to the gate-source voltage difference of the driving transistor T1 minus the threshold voltage of the driving transistor T1. This ensures that the driving current generated by the driving transistor T1 is independent of the threshold voltage of the driving transistor T1, preventing fluctuations in the threshold voltage of the driving transistor T1 from affecting the driving current.

In some embodiments, by arranging along the second direction Y, the orthographic projection of the first capacitor C1 on the substrate 110, the orthographic projection of the second capacitor C2 on the substrate 110, and the orthographic projection of the driving transistor T1 on the substrate 110 to be located between the orthographic projection of the first scan line S1 on the substrate 110 and the orthographic projection of the second scan line S2 on the substrate 110, the spacing between the orthographic projection of the first scan line S1 on the substrate 110 and the orthographic projection of the second scan line S2 on the substrate 110 is relatively large, which can reduce signal crosstalk between the first scan line S1 and the second scan line S2.

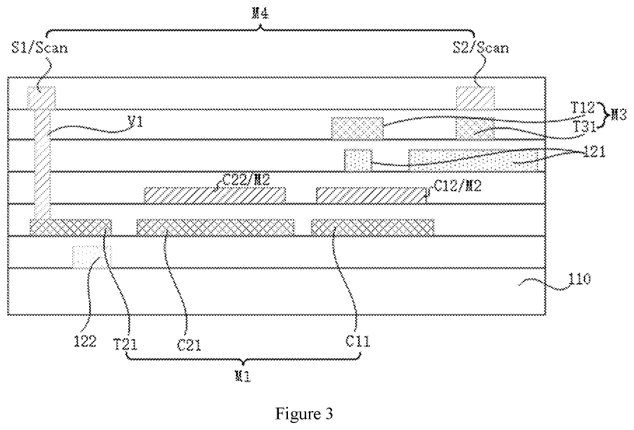

In some embodiments, FIG. 3 is a cross-sectional view along the a1-a2 direction in FIG. 1. In some embodiments, referring to FIG. 1 and FIG. 3, the active layer 120 includes a first active layer 121 and a second active layer 122. The multilayer conductive layers include a first conductive layer M1, a second conductive layer M2, and a third conductive layer M3.

The second active layer 122 is located on one side of the substrate 110. The first conductive layer M1 is located on the side of the second active layer 122 away from the substrate 110. The second conductive layer M2 is located on the side of the first conductive layer M1 away from the substrate 110. The first active layer 121 is located on the side of the second conductive layer M2 away from the substrate 110. The third conductive layer M3 is located on the side of the first active layer 121 away from the substrate 110.

The array substrate further includes a fourth conductive layer M4 located on the side of the third conductive layer M3 away from the substrate 110. At least a portion of the scan lines Scan are located in the fourth conductive layer M4. For example, the first scan line S1 connected to the second-type transistor T02 and the second scan line S2 connected to the first-type transistor T01 are located in the fourth conductive layer M4. For example, the gate T21 of the second-type transistor T02 is located in the first conductive layer M1. For example, the second gate T12 of the driving transistor T1 and the gate of the first-type transistor T01 (the third gate T31 of the threshold compensation transistor T3) are located in the third conductive layer M3.

In some embodiments, the material of the second active layer 122 is different from that of the first active layer 121. This facilitates the formation of different types of first-type transistors T01 and second-type transistors T02.

In some embodiments, the first active layer 121 includes an oxide semiconductor material, and the second active layer 122 includes a polycrystalline silicon semiconductor material. For example, the first active layer 121 includes an active region of a first-type transistor T01, and the second active layer 122 includes an active region of a second-type transistor T02. That is, the first-type transistor T01 is an oxide transistor, and the second-type transistor T02 is a polycrystalline silicon transistor. For example, the first-type transistor T01 is an N-type transistor, and the second-type transistor T02 is a P-type transistor.

In some embodiments, referring to FIG. 1, an orthographic projection of the first capacitor C1 on the substrate 110 overlaps with an orthographic projection of the driving transistor T1 on the substrate 110. In one embodiment, the space occupied by the first capacitor C1 and the driving transistor T1 can be reduced, which is beneficial for a display panel formed from the array substrate to achieve a higher pixel density.

The orthographic projection of the first capacitor C1 on the substrate 110 is spaced apart from the orthographic projection of the second capacitor C2 on the substrate 110. In one embodiment, the first capacitor C1 and the second capacitor C2 are arranged to be insulated from each other, preventing interference between the first capacitor C1 and the second capacitor C2.

In some embodiments, referring to FIG. 1 and FIG. 3, the first capacitor C1 includes a first electrode plate C11 and a second electrode plate C12, and the second capacitor C2 includes a third electrode plate C21 and a fourth electrode plate C22.

The first electrode plate C11 and the third electrode plate C21 are located in the first conductive layer M1, and the second electrode plate C12 and the fourth electrode plate C22 are located in the second conductive layer M2.

The orthographic projection of the first electrode plate C11 on the substrate 110 at least partially overlaps with the orthographic projection of the second electrode plate C12 on the substrate 110, and the orthographic projection of the third electrode plate C21 on the substrate 110 at least partially overlaps with the orthographic projection of the fourth electrode plate C22 on the substrate 110.

In some embodiments, by arranging the first electrode plate C11 and the third electrode plate C21 in the first conductive layer M1, the second electrode plate C12 and the fourth electrode plate C22 in the second conductive layer M2, and at least a portion of the scan line Scan in the fourth conductive layer M4, the number of conductive structures on the first conductive layer M1 and the second conductive layer M2 is not excessive, which is beneficial for reducing the occupied space in the first direction X and the second direction Y, and is beneficial for achieving a higher pixel density. Furthermore, crosstalk between the scan line and the first capacitor C1 and the second capacitor C2 can be reduced.

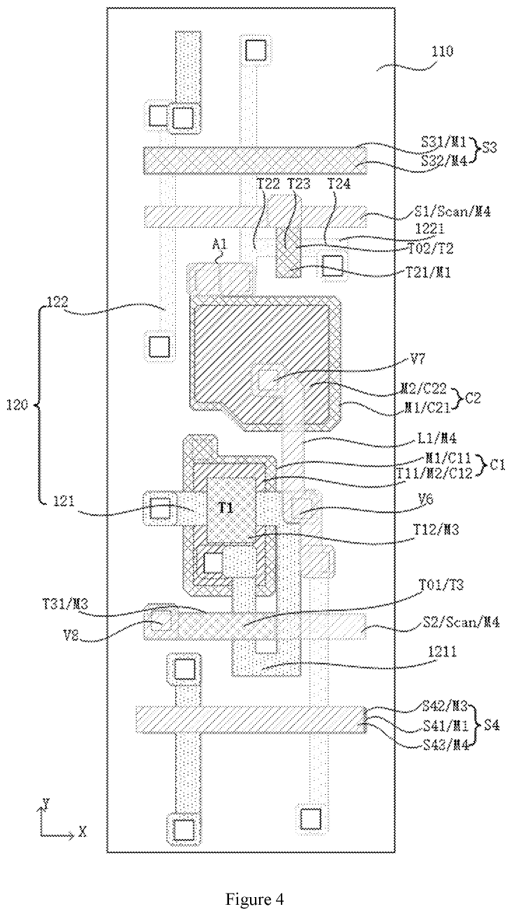

FIG. 4 is a schematic structural diagram of another array substrate provided by an embodiment of the present application. In some embodiments, referring to FIG. 4, the array substrate further includes: a first connection line L1 located in the fourth conductive layer M4, the first connection line L1 being connected between the first electrode of the driving transistor T1 and the fourth electrode plate C22.

The first connection line L1 is connected to the first electrode of the driving transistor T1 through a sixth via V6, and the first connection line L1 is connected to the fourth electrode plate C22 through a seventh via V7.

Herein, the first electrode of the driving transistor T1 is a source or a drain, which is not limited herein. By providing the first connection line L1, the first electrode of the driving transistor T1 is connected to the fourth electrode plate C22, thereby connecting the driving transistor T1 to the second capacitor C2. The sixth via V6 and the seventh via V7 are filled with a conductive material.

In some embodiments, referring to FIG. 3 and FIG. 4, the first active layer 121 includes a first active region 1211, and the second active layer 122 includes a second active region 1221.

The pixel circuit 210 includes a data writing transistor T2 and a threshold compensation transistor T3. A channel region of the data writing transistor T2 is located in the second active region 1221, and a gate T21 of the data writing transistor T2 is located in the first conductive layer M1.

The gate T21 of the data writing transistor T2 extends along the second direction Y.

A first electrode T22 of the data writing transistor T2, the channel region T23 of the data writing transistor T2, and a second electrode T24 of the data writing transistor T2 are sequentially arranged along the first direction X.

A gate of the threshold compensation transistor T3 is at least located in the third conductive layer M3, and the gate of the threshold compensation transistor T3 extends along the first direction X. A channel region of the threshold compensation transistor T3 is located in the first active region 1211. A first gate T11 of the driving transistor T1 is located in the second conductive layer M2, a second gate T12 of the driving transistor T1 is located in the third conductive layer M3, and a channel region of the driving transistor T1 is located in the first active region 1211. The first electrode T22 of the data writing transistor T2 is a source, and the second electrode T24 of the data writing transistor T2 is a drain; or, the first electrode T22 of the data writing transistor T2 is a drain, and the second electrode T24 of the data writing transistor T2 is a source. The material of the second active layer 122 includes a polycrystalline silicon semiconductor, the data writing transistor T2 is a polycrystalline silicon transistor, for example, a P-type transistor. The material of the first active layer 121 includes an oxide semiconductor, and the threshold compensation transistor T3 is an oxide transistor, for example, an N-type transistor.

In some embodiments, the first electrode T22 of the data writing transistor T2, the channel region T23 of the data writing transistor T2, and the second electrode T24 of the data writing transistor T2 are sequentially arranged along the first direction X, and the data writing transistor T2 is arranged laterally. Therefore, when the first capacitor C1 and the second capacitor C2 are arranged along the second direction Y, the lateral arrangement of the data writing transistor T2 can reduce the space in the second direction Y, achieve reasonable utilization of space, and is beneficial for improving the pixel density of the display panel formed from the array substrate.

The gate (third gate T31) of the threshold compensation transistor T3 extends along the first direction X, i.e., in the same extension direction as the second scan line S2 connected to the threshold compensation transistor T3, which can reduce the space occupied by the threshold compensation transistor T3 in the first direction X and the second direction Y.

In some embodiments, as shown in FIG. 4, the second electrode plate C12 is reused as the first gate T11. In one embodiment, the space of the driving transistor T1 can be reduced, which is beneficial for achieving a thin and light design of the array substrate.

In some embodiments, as shown in FIG. 4, the orthographic projection of the first electrode plate C11 on the substrate 110 covers the orthographic projection of the second electrode plate C12 on the substrate 110. In one embodiment, the area of the first electrode plate C11 is relatively small, that is, the area of the first gate T11 is relatively small.

In some embodiments, as shown in FIG. 4, the orthographic projection of the first gate T11 on the substrate 110 covers the orthographic projection of the second gate T12 on the substrate 110. In one embodiment, the area of the second gate T12 is relatively small, preventing the driving transistor T1 from being too large, avoiding crosstalk between the overly large driving transistor T1 and the scan line, and further improving the performance of the display panel.

In some embodiments, the channel region of the threshold compensation transistor T3 is disposed on one side of the channel region of the driving transistor T1 and is located in the same second active region 1221. The orthographic projection of the channel region T23 of the data write transistor T2 on the substrate 1 is spaced apart from the orthographic projection of the second capacitor C2 on the substrate. This ensures that no other transistors exist between the threshold compensation transistor T3, the data write transistor T2, and the driving transistor T1, guaranteeing the shortest connection trace length from the threshold compensation transistor T3 and the data write transistor T2 to the driving transistor T1, minimizing the loss of the data signal and threshold compensation signal transmitted to the driving transistor T1, and improving the driving accuracy of the pixel circuit.

In some embodiments, as shown in FIG. 3, the multilayer conductive layers further include a fourth conductive layer M4 located on a side of the third conductive layer M3 away from the substrate 110; at least two scan lines Scan include a first scan line S1 and a second scan line S2; the first scan line S1 is located in the fourth conductive layer M4; the first scan line S1 is connected to the gate T21 of the data write transistor T2 through a first via V1. The first via V1 is filled with a conductive material. In one embodiment, the first scan line S1 is connected to the gate T21 of the data write transistor T2, allowing the scan signal on the first scan line S1 to control the turn-on or turn-off of the data write transistor T2.

In some embodiments, the sheet resistance of the fourth conductive layer M4 is less than that of at least one of the first conductive layer M1, the second conductive layer M2, and the third conductive layer M3. In one embodiment, the scan line located on the fourth conductive layer M4 has a lower sheet resistance, which helps reduce signal loss on the scan line, enables more accurate control of the turn-on or turn-off of the corresponding transistor, and further improves the performance of the display panel.

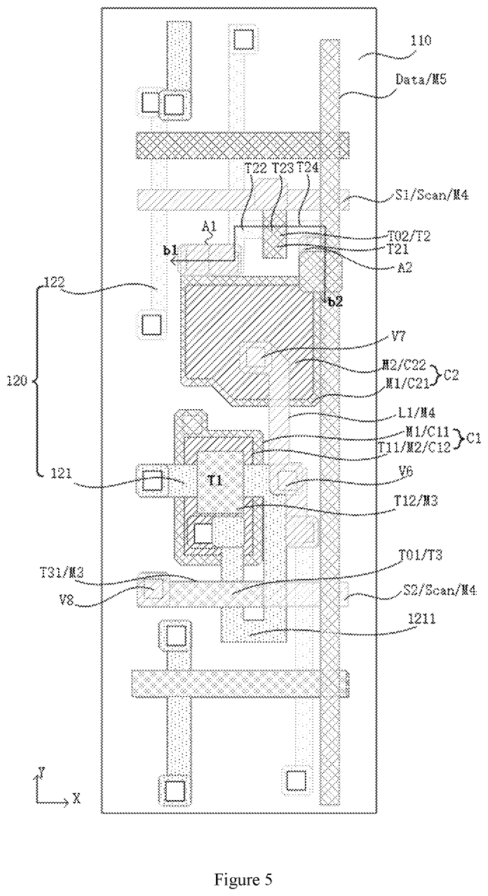

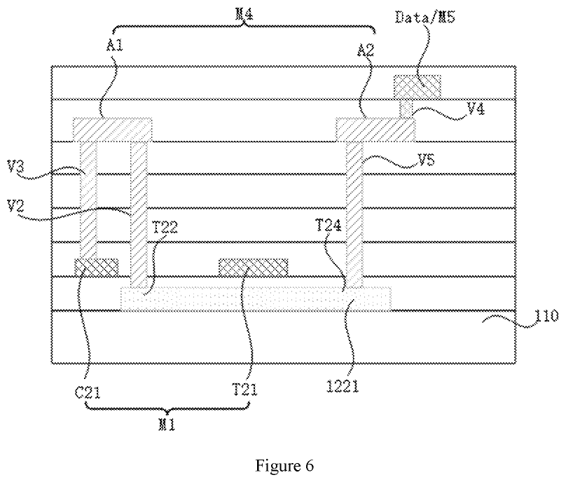

FIG. 5 is a schematic structural diagram of yet another array substrate provided by an embodiment of the present application, and FIG. 6 is a cross-sectional view taken along line b1-b2 in FIG. 5. In some embodiments, as shown in FIG. 5 and FIG. 6, the array substrate further includes: a first connection portion A1, connected between the first electrode T22 of the data write transistor T2 and the third electrode plate C21; a data line Data, extending along a second direction Y; a second connection portion A2, connected between the data line Data and the second electrode T24 of the data write transistor T2; the first connection portion A1 is located in the fourth conductive layer M4; the first connection portion A1 is connected to the first electrode T22 of the data write transistor T2 through a second via V2, and the first connection portion A1 is connected to the third electrode plate C21 through a third via V3; the second connection portion A2 is located in the fourth conductive layer M4; the second connection portion A2 is connected to the data line Data through a fourth via V4, and the second connection portion A2 is connected to the second electrode T24 of the data write transistor T2 through a fifth via V5. The second via V2, the third via V3, the fourth via V4, and the fifth via V5 are filled with a conductive material. In one embodiment, the data write transistor T2 is connected to the data line Data, and the data write transistor T2 is connected to the second capacitor C2, facilitating the transmission of the data voltage on the data line Data to the third electrode plate C21 by the data write transistor T2, and the coupling transmission of the data voltage to the driving transistor T1 by the second capacitor C2.

In some embodiments, as shown in FIG. 3, the multilayer conductive layers further include a fourth conductive layer M4 located on a side of the third conductive layer M3 away from the substrate 110; the second scan line S2 is located in the fourth conductive layer M4; the sheet resistance of the material of the fourth conductive layer M4 is less than that of at least one of the first conductive layer M1, the second conductive layer M2, and the third conductive layer M3. In one embodiment, the first scan line S1 and the second scan line S2 located on the fourth conductive layer M4 have a lower sheet resistance, which helps reduce signal loss on the first scan line S1 and the second scan line S2, enables more accurate control of the turn-on or turn-off of the corresponding transistors, and further improves the performance of the display panel.

In some embodiments, as shown in FIG. 4 or FIG. 5, the gate of the threshold compensation transistor T3 includes a third gate T31 located in the third conductive layer M3; the third gate T31 extends along a first direction X; the second scan line S2 is connected to the third gate T31 through an eighth via V8. The eighth via V8 is filled with a conductive material. In one embodiment, the second scan line S2 is connected to the gate of the threshold compensation transistor T3, allowing the scan signal on the second scan line S2 to control the turn-on or turn-off of the threshold compensation transistor T3.

In some embodiments, as shown in FIG. 4 or FIG. 5, the orthographic projection of the third gate T31 on the substrate 110 partially overlaps with the orthographic projection of the first active region 1211 on the substrate 110. That is, the channel of the threshold compensation transistor T3 overlaps with the third gate T31. The orthographic projection of the third gate T31 on the substrate 110 at least partially overlaps with the orthographic projection of the second scan line S2 on the substrate 110. This can reduce the space occupied by the third gate T31 and the second scan line S2, facilitating the achievement of high pixel density in the display panel formed by the array substrate.

In some embodiments, as shown in FIG. 4 or FIG. 5, the length of the orthographic projection of the third gate T31 on the substrate 110 in the first direction X is less than the length of the orthographic projection of the second scan line S2 on the substrate 110 in the first direction X. This can reduce the space occupied by the third gate T31, avoid interference from other signals on the third gate T31, and prevent the third gate T31 from forming additional transistors with other active regions.

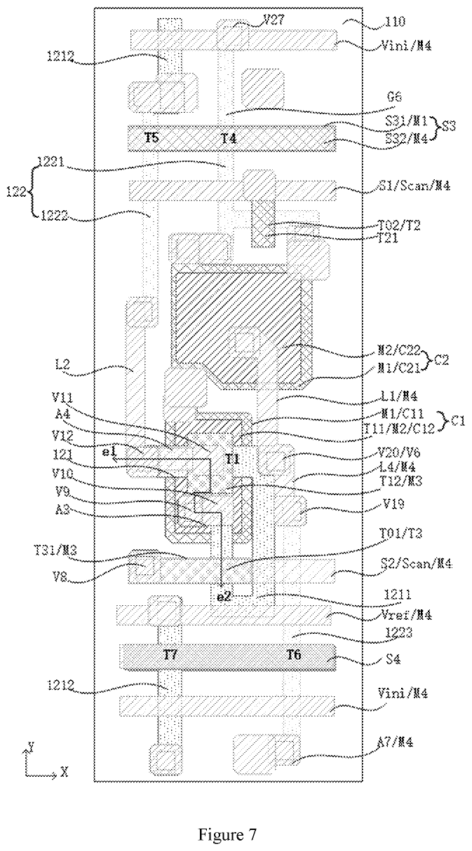

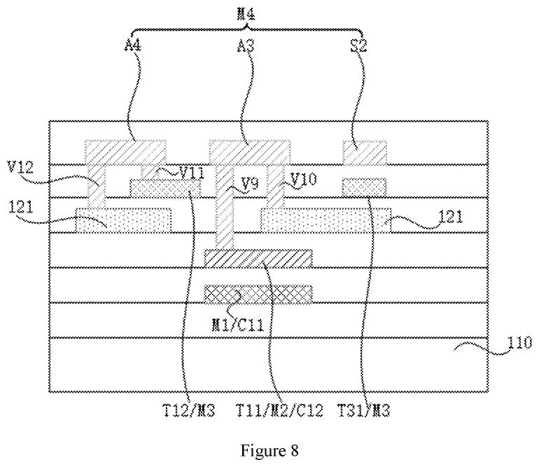

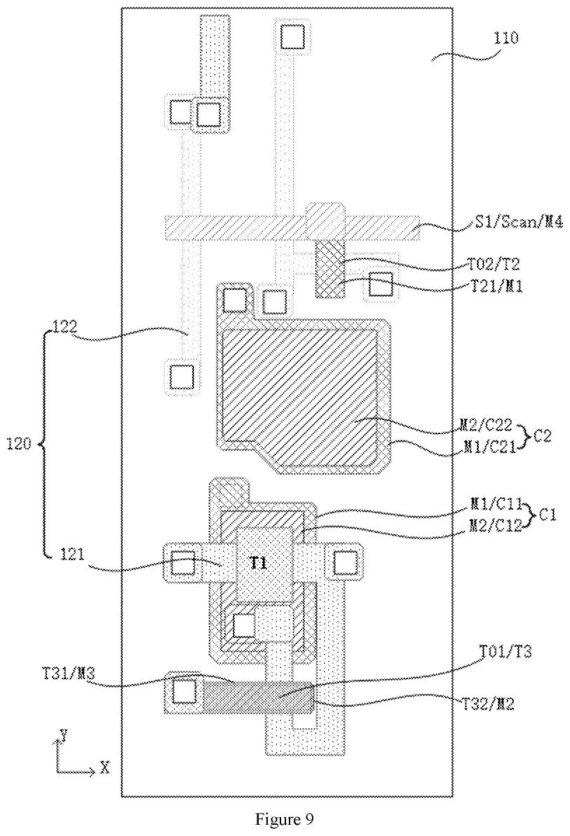

FIG. 7 is a schematic structural diagram of yet another array substrate provided by an embodiment of the present application. FIG. 8 is a schematic diagram of FIG. 7 taken along line e1-e2. In some embodiments, as shown in FIG. 7 and FIG. 8, the array substrate further includes: a third connection portion A3, connected between the first electrode of the threshold compensation transistor T3 and the second capacitor plate C12; the second electrode of the threshold compensation transistor T3 is connected to the first electrode of the driving transistor T1; a fourth connection portion A4, connected between the second gate T12 and the second electrode of the driving transistor T1; the third connection portion A3 is located in the fourth conductive layer M4; the fourth connection portion A4 is located in the fourth conductive layer; the third connection portion A3 is connected to the second capacitor plate C12 through a ninth via V9, and the third connection portion A3 is connected to the first electrode of the threshold compensation transistor T3 through a tenth via V10; the fourth connection portion A4 is connected to the second gate T12 through an eleventh via V11, and the fourth connection portion A4 is connected to the second electrode of the driving transistor T1 through a twelfth via V12. Herein, the first electrode of the driving transistor T1 is the source, and the second electrode of the driving transistor T1 is the drain; or, the first electrode of the driving transistor T1 is the drain, and the second electrode of the driving transistor T1 is the source, which is not limited herein. The first electrode of the threshold compensation transistor T3 is the source, and the second electrode of the threshold compensation transistor T3 is the drain; or, the first electrode of the threshold compensation transistor T3 is the drain, and the second electrode of the threshold compensation transistor T3 is the source, which is not limited herein. The ninth via V9, the tenth via V10, the eleventh via V11, and the twelfth via V12 are filled with a conductive material. In some embodiments, by providing the fourth connection portion A4, the second gate T12 of the driving transistor T1 can be connected to other devices through the third connection portion A3. By providing the third connection portion A3, the threshold compensation transistor T3 is connected to the second capacitor plate C12, i.e., connected to the second gate T12 of the driving transistor T1, facilitating the threshold compensation transistor T3 to transmit a voltage related to the threshold voltage of the driving transistor T1 to the second gate T12. FIG. 9 is a schematic structural diagram of yet another array substrate provided by an embodiment of the present application. In some embodiments, referring to FIG. 9, the gate of the threshold compensation transistor T3 further includes a fourth gate T32; the fourth gate T32 is located in the second conductive layer M2, and an orthographic projection of the fourth gate T32 on the substrate 110 overlaps with an orthographic projection of the second gate T31 on the substrate 110. In one embodiment, the threshold compensation transistor T3 forms a dual-gate transistor, which is beneficial for reducing leakage current. In some embodiments, FIG. 10 is a schematic structural diagram of an array substrate provided by an embodiment of the present application. In some embodiments, as shown in FIG. 10, the first active region 1211 includes a first active portion G1, a second active portion G2, a third active portion G3, and a fourth active portion G4 connected in sequence; the first active portion G1 and the third active portion G3 extend along a first direction X, and the second active portion G2 and the fourth active portion G4 extend along a second direction Y; the first active portion G1 includes a channel region of the driving transistor T1, and the fourth active portion G4 includes a channel region of the threshold compensation transistor T3; an orthographic projection of the third gate T31 on the substrate 110 overlaps with an orthographic projection of the fourth active portion G4 on the substrate 110; the orthographic projection of the third gate T31 on the substrate 110 is spaced apart from an orthographic projection of the second active portion G2 on the substrate. In one embodiment, the formation of the driving transistor T1 and the threshold compensation transistor T3 can be ensured, and the formation of an additional transistor in the second active portion G2 can be avoided. In some embodiments, as shown in FIG. 10, a first boundary D1 of the orthographic projection of the third gate T31 on the substrate 110, the orthographic projection of the fourth active portion G4 on the substrate 110, a second boundary D2 of the orthographic projection of the third gate T31 on the substrate 110, and the orthographic projection of the second active portion G2 on the substrate 110 are sequentially arranged along the first direction X. Herein, the first boundary D1 and the second boundary D2 are opposite. In one embodiment, overlap between the third gate T31 and the second active portion G2 can be avoided, preventing the second active portion G2 from forming an additional transistor. In some embodiments, the first active region 1211 is an integrated structure. In one embodiment, the preparation process can be simplified. For clearly illustrating the third gate T31, the second scan line S2 is not shown in FIG. 10. In some embodiments, as shown in FIG. 10, the second active region 1221 includes a connected fifth active portion G5 and a sixth active portion G6; the fifth active portion G5 extends along the first direction X, and the sixth active portion G6 extends along the second direction Y; a channel region of the data writing transistor T2 is located in the fifth active portion G5, and an orthographic projection of the gate T21 of the data writing transistor T2 overlaps with an orthographic projection of the fifth active portion G5; the pixel circuit 210 further includes a second reset transistor T4, and a channel region of the second reset transistor T4 is located in the sixth active portion G6. In one embodiment, the formation of the data writing transistor T2 and the second reset transistor T4 is facilitated. Herein, the second reset transistor T4 can reset the third capacitor plate C21 of the second capacitor C2, facilitating subsequent data writing to the third capacitor plate C21. The material of the second active layer 122 includes a polycrystalline silicon semiconductor, and the second reset transistor T4 is a polycrystalline silicon transistor, for example, a P-type transistor. In some embodiments, as shown in FIG. 7, the at least two scan lines include a third scan line S3; the third scan line S3 includes a first sub-line S31 located in the first conductive layer M1 and a second sub-line S32 located in the fourth conductive layer M4; an orthographic projection of the third scan line S3 on the substrate 110 partially overlaps with an orthographic projection of the sixth active portion G6 on the substrate 110. In some embodiments, the orthographic projection of the third scan line S3 on the substrate 110 partially overlaps with the orthographic projection of the sixth active portion G6 on the substrate 110, thereby forming the gate of the second reset transistor T4. The third scan line S3 includes the first sub-line S31 located in the first conductive layer M1 and the second sub-line S32 located in the fourth conductive layer M4. The material of the fourth conductive layer M4 has a low sheet resistance, which can reduce the impedance of the third scan line S3 and minimize signal loss on the third scan line S3. Moreover, this is beneficial for increasing the routing area, thereby reducing impedance and avoiding significant signal loss on the third scan line S3.

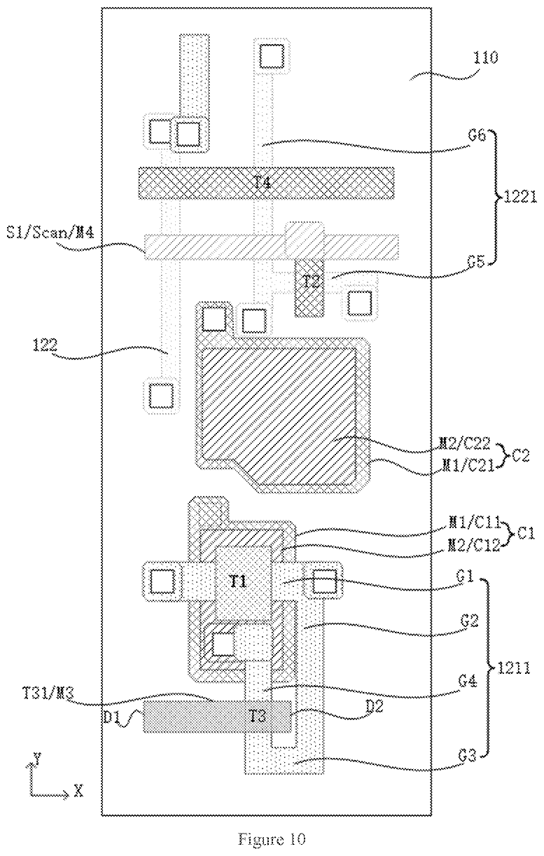

In some embodiments, the second active region 1221 is of an integrated structure. In one embodiment, the preparation process can be simplified. In some embodiments, as shown in FIG. 7, the array substrate further includes: a second reset signal line Vini, located in the fourth conductive layer M4 and extending along the first direction X. The second reset signal line Vini is connected to the second electrode of the second reset transistor T4. In the second direction Y, the orthographic projections of the second reset signal line Vini, the third scan line S3, and the first scan line S1 on the substrate 110 are sequentially arranged. The spacing between the orthographic projection of the first scan line S1 on the substrate 110 and the orthographic projection of the driving transistor T1 on the substrate 110 is smaller than the spacing between the orthographic projection of the third scan line S3 on the substrate 110 and the orthographic projection of the driving transistor T1 on the substrate 110, and is also smaller than the spacing between the orthographic projection of the second reset signal line Vini on the substrate 110 and the orthographic projection of the driving transistor T1 on the substrate 110. The first electrode of the second reset transistor T4 is connected to the first electrode of the data write transistor T2. Here, the first electrode of the second reset transistor T4 is the source electrode, and the second electrode of the second reset transistor T4 is the drain electrode; or, the first electrode of the second reset transistor T4 is the drain electrode, and the second electrode of the second reset transistor T4 is the source electrode, which is not limited herein. The second reset signal line Vini can transmit a second reset voltage. When the second reset transistor T4 is turned on, the second reset voltage on the second reset signal line Vini can be transmitted to the third capacitor plate C21 of the second capacitor C2, thereby resetting the voltage on the third capacitor plate C21 of the second capacitor C2. In some embodiments, along the second direction Y, the spacing between the orthographic projection of the first scan line S1 on the substrate 110 and the orthographic projection of the driving transistor T1 on the substrate 110 is smaller than the spacing between the orthographic projection of the third scan line S3 on the substrate 110 and the orthographic projection of the driving transistor T1 on the substrate 110, and is also smaller than the spacing between the orthographic projection of the second reset signal line Vini on the substrate 110 and the orthographic projection of the driving transistor T1 on the substrate 110. This arrangement ensures that among the first scan line S1, the third scan line S3, and the second reset signal line Vini, the first scan line S1 is closest to the driving transistor T1. Consequently, the data write transistor T2 connected to the first scan line S1 is relatively close to the driving transistor T1, facilitating the transmission of the data voltage from the data write transistor T2 to the driving transistor T1 or the second capacitor C2. In some embodiments, the second reset signal line Vini is connected to the second electrode of the second reset transistor T4 through a twenty-seventh via V27. The twenty-seventh via V27 is filled with a conductive material, thereby connecting the second reset signal line Vini to the second electrode of the second reset transistor T4. In some embodiments, as shown in FIG. 7, the second active layer 122 further includes a third active region 1222. In the first direction X, the third active region 1222 is arranged spaced apart from the second active region 1221, and the third active region 1222 extends along the second direction Y. The pixel circuit 210 further includes a first light emission control transistor T5. The channel region of the first light emission control transistor T5 is located in the third active region 1222. The orthographic projection of the third scan line S3 on the substrate 110 overlaps with the orthographic projection of the third active region 1222 on the substrate 110. Here, the material of the second active layer 122 includes a polycrystalline silicon semiconductor, and the first light emission control transistor T5 is a polycrystalline silicon transistor, for example, a P-type transistor. In some embodiments, in the first direction X, the third active region 1222 is arranged spaced apart from the second active region 1221, and the third active region 1222 extends along the second direction Y. That is, the arrangement direction of the third active region 1222 and the second active region 1221 is different from the extension direction of the third active region 1222, which can ensure rational utilization of space and is beneficial for improving the pixel density of the display panel formed by the array substrate. The orthographic projection of the third scan line S3 on the substrate 110 overlaps with the orthographic projection of the third active region 1222 on the substrate 110, thereby forming the gate of the first light emission control transistor T5. Furthermore, this allows the first light emission control transistor T5 and the second reset transistor T4 to share the third scan line S3, which can reduce the number of scan lines and is beneficial for improving the pixel density of the display panel formed by the array substrate. In some embodiments, the first sub-line S31 is multiplexed as the gate of the second reset transistor T4 and the first light emission control transistor T5. In one embodiment, the space occupied by conductive structures can be reduced, which is beneficial for achieving a thin and light design of the array substrate or improving the pixel density of the display panel formed by the array substrate. FIG. 11 is a schematic structural diagram of yet another array substrate provided by an embodiment of the present application. In some embodiments, as shown in FIG. 11, the array substrate further includes: a second connection line L2, connected between the second electrode of the driving transistor T1 and the first electrode of the first light emission control transistor T5; a third connection line L3, connected between the second electrode of the first light emission control transistor T5 and the first plate C11. In one embodiment, the second electrode of the driving transistor T1 is connected to the first electrode of the first light emission control transistor T5, and the second electrode of the first light emission control transistor T5 is connected to the first plate C11. The second electrode of the first light emission control transistor T5 can be connected to the first electrode of the light-emitting device OLED, and the second electrode of the light-emitting device OLED can be connected to the second power line VSS. Thus, when the first light emission control transistor T5 is turned on, it can transmit a driving current to the light-emitting device OLED, causing the light-emitting device OLED to emit light. Here, one of the first electrode and the second electrode of the first light emission control transistor T5 is the source electrode, and the other is the drain electrode. The light-emitting device OLED can be an organic light-emitting diode. The first electrode of the light-emitting device OLED is the anode, and the second electrode of the light-emitting device OLED is the cathode; or, the first electrode of the light-emitting device OLED is the cathode, and the second electrode of the light-emitting device OLED is the anode, which is not limited herein.

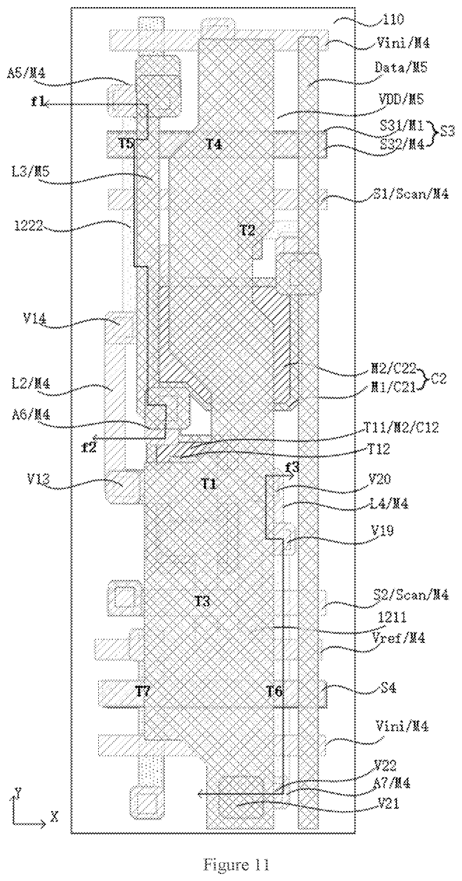

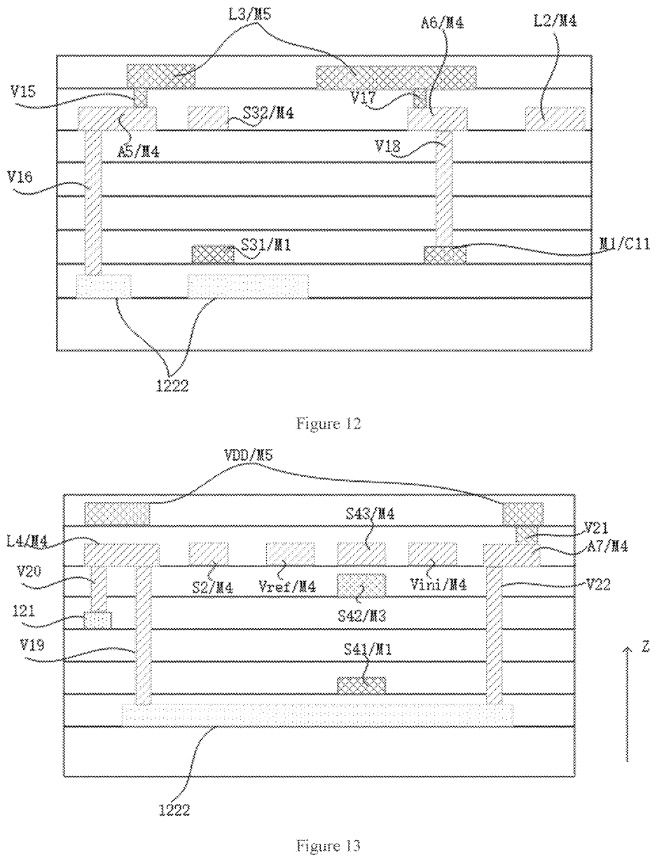

FIG. 12 is a cross-sectional view taken along line f1-f2 in FIG. 11. In some embodiments, as shown in FIG. 11 and FIG. 12, the array substrate further includes: a fifth connection portion A5 and a sixth connection portion A6. The fifth connection portion A5 is connected between a first end of the third connection line L3 and a second electrode of the first light emission control transistor T5. The sixth connection portion A6 is connected between a second end of the third connection line L3 and the first electrode plate C11. In one embodiment, the third connection line L3 connects the second electrode of the first light emission control transistor T5 and the first electrode plate C11.

In some embodiments, as shown in FIG. 11 and FIG. 12, the second connection line L2, the fifth connection portion A5, and the sixth connection portion A6 are located in a fourth conductive layer M4.

The multilayer conductive layers further include a fifth conductive layer M5 located on a side of the fourth conductive layer M4 away from the substrate.

The third connection line L3 is located in the fifth conductive layer M5.

The second connection line L2 is connected to a second electrode of the driving transistor T1 through a thirteenth via V13, and the second connection line L2 is connected to the second electrode of the first light emission control transistor T5 through a fourteenth via V14.

The fifth connection portion A5 is connected to the first end of the third connection line L3 through a fifteenth via V15, and the fifth connection portion A5 is connected to the second electrode of the first light emission control transistor T5 through a sixteenth via V16.

The sixth connection portion A6 is connected to the second end of the third connection line L3 through a seventeenth via V17, and the sixth connection portion A6 is connected to the first electrode plate C11 through an eighteenth via V18.

The thirteenth via V13, the fourteenth via V14, the fifteenth via V15, the sixteenth via V16, the seventeenth via V17, and the eighteenth via V18 are filled with a conductive material.

In one embodiment, the second electrode of the driving transistor T1 can be connected to the first electrode of the first light emission control transistor T5, and the second electrode of the first light emission control transistor T5 can be connected to the first electrode plate C11.

In some embodiments, referring to FIG. 2 and FIG. 7, the pixel circuit further includes a second light emission control transistor T6 and a first reset transistor T7.

The second active layer 122 includes a fourth active region 1223, and a channel region of the second light emission control transistor T6 is located in the fourth active region 1223.

The first active layer 121 includes a fifth active region 1212, and a channel region of the first reset transistor T7 is located in the fifth active region 1212.

Therefore, the channel type of the second light emission control transistor T6 is different from the channel type of the first reset transistor T7.

The material of the second active layer 122 includes a polycrystalline silicon semiconductor, the second light emission control transistor T6 is a polycrystalline silicon transistor, for example, a P-type transistor.

The material of the first active layer 121 includes an oxide semiconductor, the first reset transistor T7 is an oxide transistor, for example, an N-type transistor.

The first reset transistor T7 can be connected to a first electrode of the light-emitting device OLED. When the first reset transistor T7 is turned on, a first reset voltage is transmitted to the first electrode of the light-emitting device OLED to reset the first electrode of the light-emitting device OLED.

The second light emission control transistor T6 can be connected between the power line VDD and the driving transistor T1, controlling whether a first power supply voltage on the power line VDD is transmitted to the driving transistor T1.

In some embodiments, as shown in FIG. 7, in a second direction Y, orthographic projections of the fourth active region 1223 and the fifth active region 1212 located in the same pixel circuit 210 on the substrate 110 are located on different sides of orthographic projections of the first capacitor C1 and the second capacitor C2 on the substrate 110.

In a first direction X, orthographic projections of the fourth active region 1223 and the fifth active region 1212 in pixel circuits 210 adjacent in the second direction Y on the substrate 110 are arranged sequentially.

That is to say, the fourth active region 1223 and the fifth active region 1212 adjacent in the first direction X correspond to different pixel circuits 210, meaning that the second light emission control transistor T6 and the first reset transistor T7 adjacent in the first direction X are located in different pixel circuits 210.

In some embodiments, as shown in FIG. 7, the fourth active region 1223 and the fifth active region 1212 extend along the second direction Y.

In one embodiment, the extension direction of the fourth active region 1223 and the fifth active region 1212 is different from the arrangement direction of the first capacitor C1 and the second capacitor C2, allowing for more reasonable utilization of space.

In some embodiments, as shown in FIG. 7 and FIG. 11, the array substrate further includes: a power line VDD, located in a fifth conductive layer M5 on a side of the fourth conductive layer M4 away from the substrate, and extending along the second direction Y; a fourth connection line L4, connected between a first electrode of the second light emission control transistor T6 and a first electrode of the driving transistor T1; and a seventh connection portion A7, connected between the power line VDD and a second electrode of the second light emission control transistor T6.

Herein, the first electrode of the second light emission control transistor T6 is a source electrode, and the second electrode of the second light emission control transistor T6 is a drain electrode; or, the first electrode of the second light emission control transistor T6 is a drain electrode, and the second electrode of the second light emission control transistor T6 is a source electrode.

The power line VDD can provide the first power supply voltage. When the second light emission control transistor T6 is turned on, the first power supply voltage on the power line VDD can be transmitted to the first electrode of the driving transistor T1.

By providing the fourth connection line L4, the first electrode of the second light emission control transistor T6 is connected to the first electrode of the driving transistor T1. By providing the seventh connection portion A7, the power line VDD is connected to the second electrode of the second light emission control transistor T6.

FIG. 13 is a cross-sectional view taken along line f3-f4 in FIG. 11. In some embodiments, as shown in FIG. 13 and FIG. 11, the fourth connection line L4 and the seventh connection portion A7 are located in the fourth conductive layer M4.

The fourth connection line L4 is connected to the first electrode of the second light emission control transistor T6 through a nineteenth via V19, and the fourth connection line L4 is connected to the first electrode of the driving transistor T1 through a twentieth via V20.

The seventh connection portion A7 is connected to the power line VDD through a twenty-first via V21, and the seventh connection portion A7 is connected to the second electrode of the second light emission control transistor T6 through a twenty-second via V22.

The nineteenth via V19, the twentieth via V20, the twenty-first via V21, and the twenty-second via V22 are filled with conductive material, and the fourth connection line L4 connects the first electrode of the second light emission control transistor T6 to the first electrode of the driving transistor T1, and the seventh connection portion A7 connects the power line VDD to the second electrode of the second light emission control transistor T6.

In some embodiments, as shown in FIG. 7, the array substrate further includes: a first connection line L1, which is connected between the first electrode of the driving transistor T1 and the fourth electrode plate C22; the first connection line L1 is connected to the first electrode of the driving transistor T1 through the sixth via V6; the sixth via V6 is reused as the twentieth via V20. In one embodiment, space can be saved, facilitating an increase in the pixel density of the display panel formed by the array substrate.

In some embodiments, as shown in FIGS. 7, 11, and 13, the at least two scan lines include a fourth scan line S4, which includes a third sub-line S41 located in the first conductive layer M1, a fourth sub-line S42 located in the third conductive layer M3, and a fifth sub-line S43 located in the fourth conductive layer M4, all of which are interconnected; an orthographic projection of the fourth scan line S4 on the substrate 110 overlaps with an orthographic projection of the channel region of the second light emission control transistor T6 in the pixel circuit 210 of the m-th row on the substrate 110; where m is a positive integer, and each row of pixel circuits is arranged along the first direction; the orthographic projection of the fourth scan line S4 on the substrate 110 overlaps with an orthographic projection of the channel region of the first reset transistor T7 in the pixel circuit 210 of the (m+1)-th row on the substrate 110.

In some embodiments, the at least two scan lines further include a third scan line S3, which is used to drive the second reset transistor T4; the first scan line S1 is located on a side of the third scan line S3 closer to the driving transistor T1, and the second scan line S2 is located on a side of the fourth scan line S4 closer to the driving transistor T1. This arrangement ensures that the data write transistor T2 connected to the first scan line S1 and the threshold compensation transistor T3 connected to the second scan line S2 are closest to the driving transistor T1, thereby improving signal transmission accuracy; moreover, the first scan line S1 and the second scan line S2 are spaced apart by a relatively long distance, preventing signal crosstalk.

In some embodiments, along the first direction X, orthographic projections of the fourth active region 1223 and the fifth active region 1212 in adjacent pixel circuits 210 in the second direction Y on the substrate 110 are arranged sequentially, meaning that the adjacent fourth active region 1223 and fifth active region 1212 along the first direction X correspond to different pixel circuits 210. That is, the second light emission control transistor T6 and the first reset transistor T7 sharing the same fourth scan line S4 are located in different pixel circuits 210.

In the same pixel circuit 210, the scan signal on the fourth scan line S4 connected to the second light emission control transistor T6 is delayed by one row time relative to the scan signal on the fourth scan line S4 connected to the first reset transistor T7. This allows the first reset transistor T7 to first transmit the first reset voltage to the first electrode of the light-emitting device OLED to reset the first electrode of the light-emitting device OLED, after which the second light emission control transistor T6 is turned on, enabling the driving transistor T1 to generate a driving current to drive the light-emitting device OLED to emit light. Here, the row time can be determined based on the refresh rate of the display panel; for example, the reciprocal of the refresh rate of the display panel divided by the total number of rows of pixel circuits in the display panel equals one row time.

In one embodiment, sharing of scan lines can be achieved while ensuring the normal operation of the pixel circuit 210.

The fourth scan line S4 includes the interconnected third sub-line S41 located in the first conductive layer M1, the fourth sub-line S42 located in the third conductive layer M3, and the fifth sub-line S43 located in the fourth conductive layer M4. That is, the three sub-lines of the fourth scan line S4 are arranged sequentially along the thickness direction Z of the display panel, giving the fourth scan line S4 a relatively large routing area, which can reduce impedance, thereby lowering voltage drop. This is beneficial for improving the reliability of signal transmission and can reduce space in the first direction X and the second direction Y. Moreover, the sub-lines of the fourth scan line S4 in different layers can overlap with different active layers to form different types of transistors. In some embodiments, the portion where the third sub-line S41 overlaps with the fourth active region 1223 can serve as the gate of the second light emission control transistor T6, facilitating the formation of the second light emission control transistor T6, and the portion where the fourth sub-line S42 overlaps with the fifth active region 1212 can serve as the gate of the first reset transistor T7, facilitating the formation of the first reset transistor T7.

In some embodiments, a portion of the fourth scan line is reused as the gate of the second light emission control transistor T6 and the gate of the first reset transistor T7. This is beneficial for achieving a thin and lightweight design of the array substrate. For example, the first reset transistor T7 is an N-type transistor, and the fourth sub-line S42 is reused as its gate. The second light emission control transistor T6 is a P-type transistor, and the third sub-line S41 is reused as its gate.

In some embodiments, as shown in FIG. 7 or FIG. 11, the fourth conductive layer M4 further includes a first reset signal line Vref and a second reset signal line Vini extending along the first direction X; in the same pixel circuit 210 of the m-th row, orthographic projections of the first light emission control transistor T5, the second reset transistor T4, the first capacitor C1, the second capacitor C2, and the driving transistor T1 on the substrate 110 are located between the orthographic projection of the first reset signal line Vref corresponding to the pixel circuit 210 of the (m+1)-th row on the substrate 110 and the orthographic projection of the second reset signal line Vini corresponding to the pixel circuit 210 of the m-th row on the substrate 110; where m is a positive integer, and each row of pixel circuits 210 is arranged along the first direction X; in the second direction Y, the orthographic projection of the first reset signal line Vref on the substrate 110 is located on a side of the orthographic projection of the fourth scan line S4 on the substrate 110 closer to the orthographic projection of the driving transistor T1 on the substrate 110, and the second scan line S2 is located on a side of the first reset signal line Vref closer to the driving transistor T1.

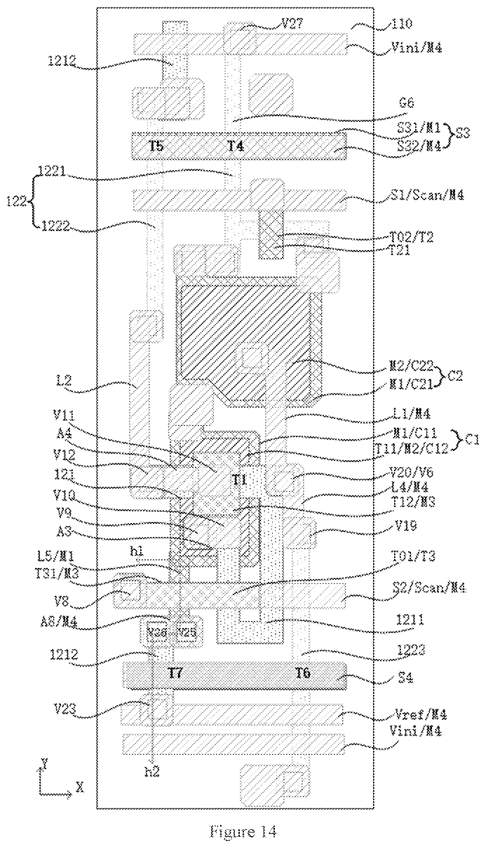

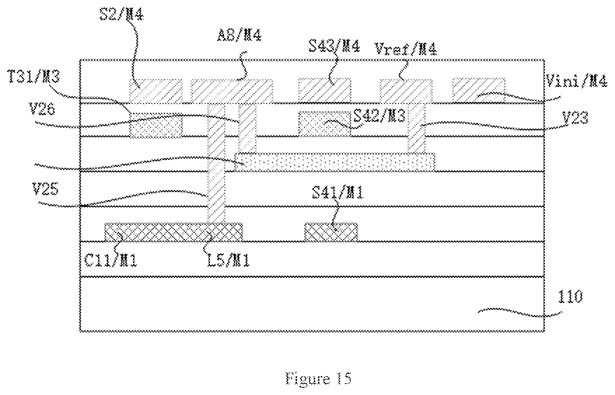

In one embodiment, the fourth scan line S4 can isolate the first reset signal line Vref from the second reset signal line Vini, avoiding signal crosstalk and further ensuring that the threshold compensation transistor T3 connected to the second scan line S2 is positioned closest to the driving transistor T1. In some embodiments, the first reset signal line Vref is connected to the first electrode of the first reset transistor T7; the second electrode of the first reset transistor T7 is connected to the second electrode of the first light emission control transistor T5. Here, the first electrode of the first reset transistor T7 is the source, and the second electrode of the first reset transistor T7 is the drain, or in one embodiment, the first electrode of the first reset transistor T7 is the drain, and the second electrode of the first reset transistor T7 is the source. In some embodiments, the orthographic projection of the first electrode plate C11 on the substrate 110, the orthographic projection of the first reset signal line Vref on the substrate 110, and the orthographic projection of the fourth scan line S4 on the substrate 110 are sequentially arranged along the second direction Y. This ensures that the distance between the fourth scan line S4 and the first reset signal line Vref is relatively short, facilitating the transmission of the first reset voltage from the first reset signal line Vref to the first reset transistor T7. In some embodiments, as shown in FIG. 7 or FIG. 11, the spacing between the orthographic projection of the fourth scan line S4 on the substrate 110 and the orthographic projection of the driving transistor T1 on the substrate 110 is greater than the spacing between the orthographic projection of the first reset signal line Vref on the substrate 110 and the orthographic projection of the driving transistor T1 on the substrate 110. That is, along the second direction Y, the orthographic projection of the first reset signal line Vref on the substrate 110 is located between the orthographic projection of the driving transistor T1 on the substrate 110 and the orthographic projection of the fourth scan line S4 on the substrate 110. In another embodiment, FIG. 14 is a schematic structural diagram of yet another array substrate provided by an embodiment of the present application. In some embodiments, referring to FIG. 14, the pixel circuit 210 further includes a second light emission control transistor T6 and a first reset transistor T7; the second active layer 122 includes a fourth active region 1223, and the channel region of the second light emission control transistor T6 is located in the fourth active region 1223; the first active layer 121 includes a fifth active region 1212, and the channel region of the first reset transistor T7 is located in the fifth active region 1212; in the second direction Y, the orthographic projections of the fourth active region 1223 and the fifth active region 1212 in the same pixel circuit 210 on the substrate 110 are located on the same side of the first capacitor C1 away from the orthographic projection of the second capacitor C2 on the substrate 110; in the first direction X, the orthographic projections of the fourth active region 1223 and the fifth active region 1212 in the same pixel circuit 210 on the substrate 110 are sequentially arranged. That is to say, the adjacent fourth active region 1223 and fifth active region 1212 along the first direction X correspond to the same pixel circuit 210, meaning that the adjacent second light emission control transistor T6 and first reset transistor T7 along the first direction X are located in the same pixel circuit 210. In some embodiments, referring to FIG. 14, both the fourth active region 1223 and the fifth active region 1212 extend along the second direction. In one embodiment, the extension directions of the fourth active region 1223 and the fifth active region 1212 differ from the arrangement direction of the first capacitor C1 and the second capacitor C2, allowing for more efficient use of space. In some embodiments, referring to FIG. 14, the at least two scan lines include a fourth scan line S4, and the fourth scan line S4 includes a third sub-line S41 located in the first conductive layer M1, a fourth sub-line S42 located in the third conductive layer M3, and a fifth sub-line S43 located in the fourth conductive layer M4; the orthographic projection of the fourth scan line S4 on the substrate 110 overlaps with the orthographic projections of the channel region of the second light emission control transistor T6 and the channel region of the first reset transistor T7 in the m-th row pixel circuit 210 on the substrate 110; where m is a positive integer, and each row of pixel circuits 210 is arranged along the first direction X. In one embodiment, the second light emission control transistor T6 and the first reset transistor T7 located in the same pixel circuit 210 can share a single fourth scan line S4, facilitating an increase in the pixel density of the display panel formed by the array substrate. In this case, the signals on the fourth scan line S4 connected to the second light emission control transistor T6 and the fourth scan line S4 connected to the first reset transistor T7 in the same pixel circuit 210 are the same. In some embodiments, referring to FIG. 14, the fourth conductive layer M4 further includes a first reset signal line Vref and a second reset signal line Vini extending along the first direction X; within the same pixel circuit 210, the orthographic projections of the first light emission control transistor T5, the second reset transistor T4, the first capacitor C1, the second capacitor C2, and the driving transistor T1 on the substrate 110 are located between the orthographic projections of the first reset signal line Vref and the second reset signal line Vini on the substrate 110. In one embodiment, the spacing between the first reset signal line Vref and the second reset signal line Vini is relatively large, avoiding signal crosstalk. In some embodiments, referring to FIG. 14, in the second direction Y, the orthographic projection of the first reset signal line Vref on the substrate 110 is located on the side of the orthographic projection of the fourth scan line S4 on the substrate 110 away from the orthographic projection of the driving transistor T1 on the substrate 110. In some embodiments, the array substrate further includes a fifth connection line L5, connected between the second electrode of the first reset transistor T7 and the first electrode plate C11; the fifth connection line L5 extends along the second direction Y, and the orthographic projection of the fifth connection line L5 on the substrate 110 overlaps with the orthographic projection of the second scan line S2 on the substrate 110. In one embodiment, the second electrode of the first reset transistor T7 is connected to the first electrode plate C11 of the first capacitor C1. Moreover, the orthographic projection of the fifth connection line L5 on the substrate 110 overlaps with the orthographic projection of the second scan line S2 on the substrate 110, which can reduce the space occupied by the fifth connection line L5. FIG. 15 is a cross-sectional view taken along line h1-h2 in FIG. 14. In some embodiments, referring to FIG. 14 and FIG. 15, the first reset signal line Vref is located in the fourth conductive layer M4, and the fifth connection line L5 is arranged in the same layer as the first electrode plate C11. This facilitates the connection between the fifth connection line L5 and the first electrode plate C11 and can reduce the number of vias.

In some embodiments, referring to FIG. 14 and FIG. 15, the first reset signal line Vref is connected to the first electrode of the first reset transistor T7 through the twenty-third via V23. In one embodiment, the first reset signal line Vref is connected to the first electrode of the first reset transistor T7.

In some embodiments, referring to FIG. 14 and FIG. 15, the array substrate further includes:
an eighth connection portion A8, connected between the first end of the fifth connection line L5 and the second electrode of the first reset transistor T7; the second end of the fifth connection line L5 is connected to the first electrode plate C11. In one embodiment, the first end of the fifth connection line L5 is connected to the second electrode of the first reset transistor T7.

In some embodiments, referring to FIG. 14 and FIG. 15, the eighth connection portion A8 is connected to the first end of the fifth connection line L5 through the twenty-fifth via V25, and the eighth connection portion A8 is connected to the second electrode of the first reset transistor T7 through the twenty-sixth via V26;
the eighth connection portion A8 is located in the fourth conductive layer M4.

In one embodiment, the eighth connection portion A8 connects the first end of the fifth connection line L5 to the second electrode of the first reset transistor T7.

In some embodiments, as shown in FIG. 11, the array substrate further includes: a fifth conductive layer M5 located on a side of the fourth conductive layer M4 away from the fourth conductive layer M4, and the fifth conductive layer M5 includes a data line Data and a power line VDD extending along the second direction Y;
at least a portion of an orthographic projection of the power line VDD on the substrate 110 is located between an orthographic projection of the data line Data on the substrate 110 and an orthographic projection of the first gate T11 on the substrate 110;
at least a portion of the orthographic projection of the power line VDD on the substrate 110 is located between the orthographic projection of the data line Data on the substrate 110 and an orthographic projection of the second gate T12 on the substrate 110.

In one embodiment, the power line VDD can shield the gate (the first gate T11 and the second gate T12) of the driving transistor T1 from the data line Data, preventing the data line Data from interfering with the voltage of the gate (the first gate T11 and the second gate T12) of the driving transistor T1. Moreover, the layout design of the array substrate can be made compact, achieving reasonable utilization of space, which facilitates improving the pixel density of the display panel formed by the array substrate.

In some embodiments, as shown in FIG. 11, the orthographic projection of the power line VDD on the substrate 110 covers at least a portion of an orthographic projection of the first active region 1211 on the substrate 110.

In some embodiments, as shown in FIG. 11, the orthographic projection of the power line VDD on the substrate 110 covers an orthographic projection of the first capacitor C1 on the substrate 110. In one embodiment, the space occupied by the power line VDD and the pixel circuit 210 in the first direction X and the second direction Y can be reduced, facilitating an improvement in the pixel density of the display panel formed by the array substrate.

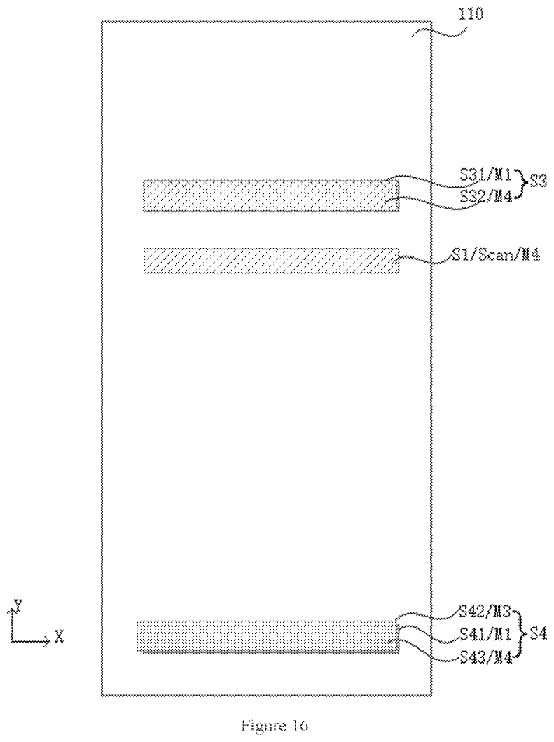

Embodiments of the present application also provide an array substrate. FIG. 16 is a schematic structural diagram of yet another array substrate provided by an embodiment of the present application. Referring to FIG. 16, the array substrate includes:
a substrate 110;
a first conductive layer M1, a third conductive layer M3, and a fourth conductive layer M4 sequentially stacked along a direction away from the substrate 110;
a first scan line S1, located in the fourth conductive layer M4;
a third scan line S3, located in the first conductive layer M1 and the fourth conductive layer M4;
a fourth scan line S4, located in the first conductive layer M1, the third conductive layer M3, and the fourth conductive layer M4; in one embodiment, orthographic projections of the first scan line S1, the third scan line S3, and the fourth scan line S4 on the substrate 110 all extend along the first direction X and are arranged at intervals along the second direction Y, and the first direction X and the second direction Y are arranged intersecting each other.

In some embodiments, by arranging the orthographic projections of the first scan line S1, the third scan line S3, and the fourth scan line S4 on the substrate 110 to be spaced apart along the second direction Y, signal crosstalk between different scan lines can be avoided, which is beneficial for improving the performance of the display panel formed by the array substrate. Moreover, the sheet resistance of the fourth conductive layer M4 can be less than the sheet resistance of at least one of the first conductive layer M1, the second conductive layer M2, and the third conductive layer M3. At least portions of the first scan line S1, the third scan line S3, and the fourth scan line S4 are located in the fourth conductive layer M4, making the sheet resistance of the first scan line S1, the third scan line S3, and the fourth scan line S4 relatively small, thereby resulting in a smaller voltage drop loss. This is beneficial for reducing signal loss on the scan lines, enabling more accurate control of the turn-on or turn-off of corresponding transistors, and further improving the performance of the display panel.

Furthermore, the third scan line S3 is located in the first conductive layer M1 and the fourth conductive layer M4, and the fourth scan line S4 is located in the first conductive layer M1, the third conductive layer M3, and the fourth conductive layer M4, which can enhance the signal transmission capability of the third scan line S3 and the fourth scan line S4. This is beneficial for reducing wiring resistance and power consumption, while improving driving stability, enabling more accurate control of the turn-on or turn-off of corresponding transistors. Moreover, sub-lines of different layers of the fourth scan line S4 can overlap with different active layers, thereby allowing the formation of different types of transistors.

In some embodiments, as shown in FIG. 16, the third scan line S3 includes a first sub-line S31 located in the first conductive layer M1 and a second sub-line S32 located in the fourth conductive layer M4;
the fourth scan line S4 includes a third sub-line S41 located in the first conductive layer M1, a fourth sub-line S42 located in the third conductive layer M3, and a fifth sub-line S43 located in the fourth conductive layer M4.

The first sub-line S31 and the second sub-line S32 in FIG. 16 are stacked together. The specific positional relationship between the first sub-line S31 and the second sub-line S32 can be referred to in FIG. 12. Similarly, the specific positional relationship between the third sub-line S41, the fourth sub-line S42, and the fifth sub-line S43 can be referred to in FIG. 13.

In some embodiments, as shown in FIG. 2 and FIG. 7, the array substrate further includes: an active layer 120 disposed on one side of the substrate 110 in a stacked manner, and the active layer 120 and the multilayer conductive layers form at least one pixel circuit 210, and the pixel circuit 210 includes a first capacitor C1, a second capacitor C2, and a driving transistor T1; the array substrate further includes: a second scan line S2, located in a second conductive layer M2, and the second conductive layer M2 is located on a side of a first conductive layer M1 away from the substrate 110; along a second direction Y, an orthographic projection of the first capacitor C1 on the substrate 110, an orthographic projection of the second capacitor C2 on the substrate 110, and an orthographic projection of the driving transistor T1 on the substrate 110 are located between an orthographic projection of a first scan line S1 on the substrate 110 and an orthographic projection of the second scan line S2 on the substrate 110; the pixel circuit 210 further includes a data writing transistor T2, a threshold compensation transistor T3, a first light emission control transistor T5, a second light emission control transistor T6, a first reset transistor T7, and a second reset transistor T4, and the first scan line S1 is connected to a gate of the data writing transistor T2, the second scan line S2 is connected to a gate of the threshold compensation transistor T3, a third scan line S3 is connected to a gate of the first reset transistor T7 and a gate of the second light emission control transistor T6, and a fourth scan line S4 is connected to a gate of the second reset transistor T4 and a gate of the first light emission control transistor T5.

In some embodiments, along the second direction Y, the orthographic projection of the first capacitor C1 on the substrate 110, the orthographic projection of the second capacitor C2 on the substrate 110, and the orthographic projection of the driving transistor T1 on the substrate 110 are located between the orthographic projection of the first scan line S1 on the substrate 110 and the orthographic projection of the second scan line S2 on the substrate 110, which can separate the first scan line S1 from the second scan line S2, thereby avoiding crosstalk between signals on the first scan line S1 and signals on the second scan line S2.

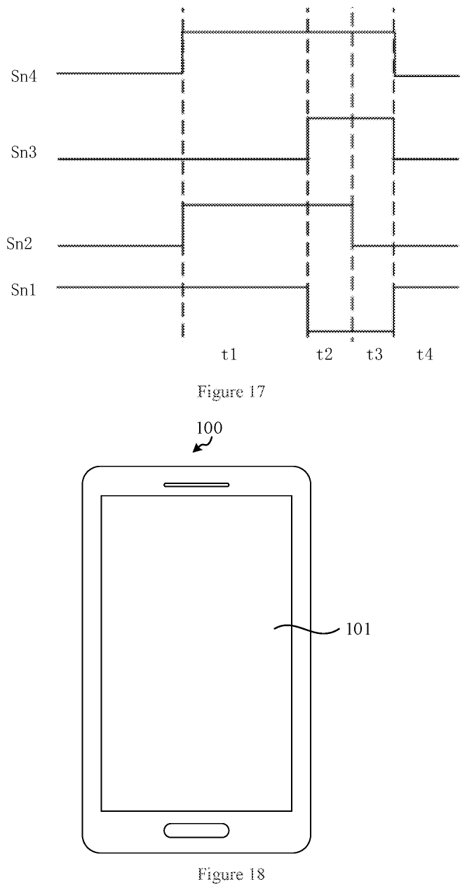

FIG. 17 is a timing diagram of a pixel circuit provided by an embodiment of the present application. As shown in FIG. 2 and FIG. 7, the working process of the pixel circuit includes the following stages. The working process of the pixel circuit is described below by taking as an example that a scan signal on the fourth scan line S4 connected to the first reset transistor T7 is the same as a scan signal on the fourth scan line S4 connected to the second light emission control transistor T6.

In a first stage t1, a first scan signal Sn1 on the first scan line S1 is at a high level, and the data writing transistor T2 is turned off. A second scan signal Sn2 on the second scan line S2 is at a high level, and the threshold compensation transistor T3 is turned on. A third scan signal Sn3 on the third scan line S3 is at a low level, and the second reset transistor T4 and the first light emission control transistor T5 are turned on. A fourth scan signal Sn4 on the fourth scan line S4 is at a high level, and the first reset transistor T7 is turned on. The first reset transistor T7 transmits a first reset voltage on a first reset signal line Vref to a first terminal of a light-emitting device OLED to reset the first terminal of the light-emitting device OLED. The second reset transistor T4 transmits a second reset voltage on a second reset signal line Vini to a first terminal (a third capacitor plate C21) of the second capacitor C2 to reset the first terminal of the second capacitor C2. The first light emission control transistor T5 transmits the first reset voltage to a second terminal of the driving transistor T1 to reset the second terminal of the driving transistor T1. The threshold compensation transistor T3 transmits a voltage of a first terminal of the driving transistor T1 to a gate of the driving transistor T1, and a voltage at the gate of the driving transistor T1 is a voltage provided by a power line VDD, and a voltage difference is formed between the gate of the driving transistor T1 and the second terminal of the driving transistor T1, and the gate of the driving transistor T1 discharges until it reaches a sum of the first reset voltage and a threshold voltage of the driving transistor T1.

In a second stage t2, the first scan signal Sn1 on the first scan line S1 is at a low level, and the data writing transistor T2 is turned on. The second scan signal Sn2 on the second scan line S2 is at a high level, and the threshold compensation transistor T3 is turned on. The third scan signal Sn3 on the third scan line S3 is at a high level, and the second reset transistor T4 and the first light emission control transistor T5 are turned off. The fourth scan signal Sn4 on the fourth scan line S4 is at a high level, and the first reset transistor T7 is turned on. The first reset transistor T7 transmits the first reset voltage on the first reset signal line Vref to the first terminal of the light-emitting device OLED to reset the first terminal of the light-emitting device OLED. The data writing transistor T2 transmits a data voltage to the first terminal of the second capacitor C2, the second capacitor C2 couples the data voltage to the first terminal of the driving transistor T1, and the threshold compensation transistor T3 transmits a voltage related to the data voltage to the gate of the driving transistor T1, and the voltage at the gate of the driving transistor T1 is a voltage related to the data voltage and the threshold voltage of the driving transistor T1.

In a third stage t3, the first scan signal Sn1 on the first scan line S1 is at a low level, and the data writing transistor T2 is turned on. The second scan signal Sn2 on the second scan line S2 is at a low level, and the threshold compensation transistor T3 is turned off. The third scan signal Sn3 on the third scan line S3 is at a high level, and the second reset transistor T4 and the first light emission control transistor T5 are turned off. The fourth scan signal Sn4 on the fourth scan line S4 is at a high level, and the first reset transistor T7 is turned on. The first reset transistor T7 transmits the first reset voltage on the first reset signal line Vref to the first terminal of the light-emitting device OLED to reset the first terminal of the light-emitting device OLED.

In a fourth stage t4, the first scan signal Sn1 on the first scan line S1 is at a high level, and the data writing transistor T2 is turned off. The second scan signal Sn2 on the second scan line S2 is at a low level, and the threshold compensation transistor T3 is turned off. The third scan signal Sn3 on the third scan line S3 is at a low level, and the first light emission control transistor T5 is turned on. The fourth scan signal Sn4 on the fourth scan line S4 is at a low level, the first reset transistor T7 is turned off, and the second light emission control transistor T6 is turned on, and the driving transistor T1 generates a driving current to drive the light-emitting device OLED to emit light.

In some embodiments, as shown in FIG. 2 and FIG. 7, the orthographic projection of the first capacitor C1 on the substrate 110 overlaps with the orthographic projection of the driving transistor T1 on the substrate 110; the orthographic projection of the first capacitor C1 on the substrate 110 does not overlap with the orthographic projection of the second capacitor C2 on the substrate 110. In one embodiment, the occupied space of the first capacitor C1 and the driving transistor T1 can be reduced, which is beneficial for the display panel formed by the array substrate to achieve a higher pixel density. Moreover, the first capacitor C1 and the second capacitor C2 are insulated from each other, avoiding interference between the first capacitor C1 and the second capacitor C2.

In some embodiments, referring to FIG. 3 and FIG. 4, the active layer 120 includes a first active layer 121 and a second active layer 122, the second active layer 122 is located on a side of the substrate 110, the first conductive layer M1 is located on a side of the second active layer 122 away from the substrate 110, the second conductive layer M2 is located on a side of the first conductive layer M1 away from the substrate 110, the first active layer 121 is located on a side of the second conductive layer M2 away from the substrate 110, and the third conductive layer M3 is located on a side of the first active layer 121 away from the substrate 110; the first active layer 121 includes a first active region 1211, and the second active layer 122 includes a second active region 1221; the channel region of the data writing transistor T2 is located in the second active region 1221, and the gate of the data writing transistor T2 is located in the first conductive layer M1; the gate of the data writing transistor T2 extends along the second direction Y; the first electrode, the channel region, and the second electrode of the data writing transistor T2 are sequentially arranged along the first direction X; the gate of the threshold compensation transistor T3 is at least located in the third conductive layer, and the gate of the threshold compensation transistor T3 extends along the first direction X, and the channel region of the threshold compensation transistor T3 is located in the first active region 1211; the first gate T11 of the driving transistor T1 is located in the second conductive layer M2, the second gate T12 of the driving transistor T1 is located in the third conductive layer M3, and the channel region of the driving transistor T1 is located in the first active region 1211.

In some embodiments, as shown in FIG. 4, the second electrode plate C12 is reused as the first gate T11.

In some embodiments, as shown in FIG. 4, the orthographic projection of the first electrode plate C11 on the substrate 110 covers the orthographic projection of the second electrode plate C21 on the substrate 110.

In some embodiments, as shown in FIG. 4, the orthographic projection of the first gate T11 on the substrate 110 covers the orthographic projection of the second gate on the substrate.

The beneficial effects of the array substrate of this embodiment are the same as those of the array substrate shown in FIG. 4, and will not be repeated here.

In some embodiments, the first active region 1211 includes a first active portion G1, a second active portion G2, a third active portion G3, and a fourth active portion G4 which are sequentially connected; the first active portion G1 and the third active portion G3 extend along the first direction X, and the second active portion G2 and the fourth active portion G4 extend along the second direction Y; the first active portion G1 includes the channel region of the driving transistor T1, and the fourth active portion G4 includes the channel region of the threshold compensation transistor T3; the orthographic projection of the third gate T31 on the substrate 110 overlaps with the orthographic projection of the fourth active portion G4 on the substrate 110; the orthographic projection of the third gate T31 on the substrate 110 is spaced apart from the orthographic projection of the second active portion G2 on the substrate 110.

In some embodiments, the first boundary D1 of the orthographic projection of the third gate T31 on the substrate 110, the orthographic projection of the fourth active portion G4 on the substrate 110, the second boundary D2 of the orthographic projection of the third gate T31 on the substrate 110, and the orthographic projection of the second active portion G2 on the substrate 110 are sequentially arranged along the first direction X.

In some embodiments, the first active region 1211 is an integrated structure.

The beneficial effects of the array substrate of this embodiment are the same as those of the array substrate shown in FIG. 10, and will not be repeated here.

Embodiments of the present application also provide a display panel. FIG. 18 is a schematic structural diagram of a display panel provided by an embodiment of the present application. Referring to FIG. 18, the display panel 100 includes the array substrate 101 provided by any embodiment of the present application. The display panel 100 may further include a light-emitting device OLED. The pixel circuit 210 in the array substrate 101 is connected to the light-emitting device OLED to drive the light-emitting device OLED to emit light. The display panel 100 includes the array substrate 101 provided by any embodiment of the present application, and therefore has the same beneficial effects as the array substrate provided by any embodiment of the present application, which will not be repeated here. The display panel may be any product or component with a display function, such as a mobile phone, tablet computer, television, monitor, laptop computer, digital photo frame, etc.

The above specific implementations do not constitute a limitation on the protection scope of the present application. It should be understood that various modifications, combinations, sub-combinations, and substitutions can be made according to design requirements and other factors. Any modifications, equivalent replacements, and improvements made within the spirit and principles of the present application shall be included within the protection scope of the present application.

What is claimed is

1. An array substrate, comprising:
a substrate;
at leat one active layer and a plurality of conductive layers stacked on one side of the substrate, the at leat one active layer and the plurality of conductive layers forming at least one pixel circuit, the pixel circuit comprising a first capacitor, a second capacitor, a driving transistor, and a plurality of switching transistors;
wherein the plurality of conductive layers comprises at least two scan lines, the scan lines extending along a first direction, the driving transistor and the plurality of switching transistors being each connected to one of the scan lines;
the plurality of switching transistors comprise a first-type transistor and a second-type transistor; along a second direction, an orthographic projection of the first capacitor on the substrate, an orthographic projection of the second capacitor on the substrate, and an orthographic projection of the driving transistor on the substrate are located between orthographic projections on the substrate of any two of the scan lines, the two scan lines being respectively connected to the first-type transistor and the second-type transistor, and the first capacitor and the second capacitor are arranged along the second direction, and the second direction intersects the first direction.

2. The array substrate according to claim 1, wherein the at least two scan lines comprise a first scan line and a second scan line;
the plurality of switching transistors comprise a data writing transistor and a threshold compensation transistor;
the first scan line is connected to a gate of the data writing transistor, and the second scan line is connected to a gate of the threshold compensation transistor;
along the second direction, the orthographic projection of the first capacitor on the substrate, the orthographic projection of the second capacitor on the substrate, and the orthographic projection of the driving transistor on the substrate are all located within a region defined between an orthographic projection of the first scan line on the substrate and an orthographic projection of the second scan line on the substrate;
the threshold compensation transistor is the first-type transistor, and the data writing transistor is the second-type transistor;
one of the first-type transistor and the second-type transistor is an N-type transistor, and the other is a P-type transistor.

3. The array substrate according to claim 1, wherein the at leat one active layer comprises a first active layer and a second active layer, and the plurality of conductive layers comprise a first conductive layer, a second conductive layer, and a third conductive layer;
the second active layer is located on one side of the substrate, the first conductive layer is located on a side of the second active layer away from the substrate, the second conductive layer is located on a side of the first conductive layer away from the substrate, the first active layer is located on a side of the second conductive layer away from the substrate, and the third conductive layer is located on a side of the first active layer away from the substrate;
the orthographic projection of the first capacitor on the substrate overlaps with the orthographic projection of the driving transistor on the substrate;
the orthographic projection of the first capacitor on the substrate is spaced apart from the orthographic projection of the second capacitor on the substrate.

4. The array substrate according to claim 3, wherein the first active layer comprises a first active region, and the second active layer comprises a second active region;
the plurality of switching transistors comprise a data writing transistor and a threshold compensation transistor, a channel region of the data writing transistor is located in the second active region, and a gate of the data writing transistor is located in the first conductive layer;
the gate of the data writing transistor extends along the second direction;
a first electrode of the data writing transistor, the channel region of the data writing transistor, and a second electrode of the data writing transistor are sequentially arranged along the first direction;
a gate of the threshold compensation transistor is at least located in the third conductive layer, and the gate of the threshold compensation transistor extends along the first direction, a channel region of the threshold compensation transistor is located in the first active region; a first gate of the driving transistor is located in the second conductive layer, a second gate of the driving transistor is located in the third conductive layer, and a channel region of the driving transistor is located in the first active region;
the first capacitor comprises a first electrode plate and a second electrode plate, the second capacitor comprises a third electrode plate and a fourth electrode plate, the second electrode plate is reused as the first gate, an orthographic projection of the first electrode plate on the substrate covers an orthographic projection of the second electrode plate on the substrate, and an orthographic projection of the first gate on the substrate covers an orthographic projection of the second gate on the substrate.

5. The array substrate according to claim 3, wherein the plurality of conductive layers further comprises a fourth conductive layer located on a side of the third conductive layer away from the substrate;
the at least two scan lines comprise a first scan line and a second scan line; the first scan line is located in the fourth conductive layer;
the first scan line is connected to the gate of the data writing transistor through a first via;
a sheet resistance of the fourth conductive layer is less than a sheet resistance of at least one of the first conductive layer, the second conductive layer, and the third conductive layer.

6. The array substrate according to claim 4, wherein at least two scan lines comprise a first scan line and a second scan line;
the plurality of conductive layers further comprise a fourth conductive layer located on a side of the third conductive layer away from the substrate;
the second scan line is located in the fourth conductive layer;
a sheet resistance of the fourth conductive layer is less than a sheet resistance of at least one of the first conductive layer, the second conductive layer, and the third conductive layer;
a gate of the threshold compensation transistor comprises a third gate located in the third conductive layer; the third gate extends along the first direction;
the second scan line is connected to the third gate;
an orthographic projection of the third gate on the substrate at least partially overlaps an orthographic projection of the second scan line on the substrate;
a length of the orthographic projection of the third gate on the substrate in the first direction is less than a length of the orthographic projection of the second scan line on the substrate in the first direction;
the gate of the threshold compensation transistor further comprises a fourth gate;
the fourth gate is located in the second conductive layer, and an orthographic projection of the fourth gate on the substrate overlaps an orthographic projection of the second gate on the substrate.

7. The array substrate according to claim 6, wherein the first active region comprises a first active portion, a second active portion, a third active portion, and a fourth active portion which are sequentially connected;
the first active portion and the third active portion extend along the first direction, and the second active portion and the fourth active portion extend along the second direction;
the first active portion comprises a channel region of the driving transistor, and the fourth active portion comprises a channel region of the threshold compensation transistor;
an orthographic projection of the third gate on the substrate overlaps an orthographic projection of the fourth active portion on the substrate; the orthographic projection of the third gate on the substrate is spaced apart from an orthographic projection of the second active portion on the substrate;
a first boundary of the orthographic projection of the third gate on the substrate, the orthographic projection of the fourth active portion on the substrate, a second boundary of the orthographic projection of the third gate on the substrate, and the orthographic projection of the second active portion on the substrate are sequentially arranged along the first direction;
the first active region is an integrated structure.

8. The array substrate according to claim 4, wherein the second active region comprises a connected fifth active portion and a sixth active portion, the fifth active portion extends along the first direction, and the sixth active portion extends along the second direction;
a channel region of the data writing transistor is located in the fifth active portion, and an orthographic projection of the gate of the data writing transistor on the substrate overlaps an orthographic projection of the fifth active portion on the substrate;
the plurality of switching transistors further comprise a second reset transistor, and a channel region of the second reset transistor is located in the sixth active portion;
the at least two scan lines comprise a third scan line; the third scan line comprises a first sub-line located in the first conductive layer and a second sub-line located in the fourth conductive layer;
an orthographic projection of the third scan line on the substrate partially overlaps an orthographic projection of the sixth active portion on the substrate;
the at least two scan lines further comprises:
a second reset signal line, located in the fourth conductive layer and extending along the first direction, the second reset signal line being connected to a second electrode of the second reset transistor, wherein in the second direction, orthographic projections of the second reset signal line, the third scan line, and the first scan line on the substrate are sequentially arranged, a spacing between an orthographic projection of the first scan line on the substrate and an orthographic projection of the driving transistor on the substrate is less than a spacing between the orthographic projection of the third scan line on the substrate and the orthographic projection of the driving transistor on the substrate, and is less than a spacing between an orthographic projection of the second reset signal line on the substrate and the orthographic projection of the driving transistor on the substrate;
a first electrode of the second reset transistor is connected to a first electrode of the data writing transistor.

9. The array substrate according to claim 8, wherein the second active layer further comprises a third active region, in the first direction, the third active region and the second active region are arranged spaced apart, and the third active region extends along the second direction;
the plurality of switching transistors further comprises a first light emission control transistor;
a channel region of the first light emission control transistor is located in the third active region;
an orthographic projection of the third scan line on the substrate overlaps an orthographic projection of the third active region on the substrate; the first sub-line is reused as a gate of the second reset transistor and a gate of the first light emission control transistor.

10. The array substrate according to claim 3, wherein the plurality of switching transistors comprises a second light emission control transistor and a first reset transistor;
the second active layer comprises a fourth active region, and a channel region of the second light emission control transistor is located in the fourth active region;
the first active layer comprises a fifth active region, and a channel region of the first reset transistor is located in the fifth active region;
in the second direction, orthographic projections of the fourth active region and the fifth active region in the same pixel circuit on the substrate are located on different sides of orthographic projections of the first capacitor and the second capacitor on the substrate;
in the first direction, orthographic projections of the fourth active region and the fifth active region in the pixel circuits adjacent to each other in the second direction on the substrate are sequentially arranged;
the fourth active region and the fifth active region extend along the second direction.

11. The array substrate according to claim 10, wherein the plurality of conductive layers comprises a fifth conductive layer located on a side of the fourth conductive layer away from the substrate, the fifth conductive layer comprises a data line and a power line extending along a second direction;
at least a portion of an orthographic projection of the power line on the substrate is located between an orthographic projection of the data line on the substrate and an orthographic projection of the first gate on the substrate;
at least a portion of the orthographic projection of the power line on the substrate is located between the orthographic projection of the data line on the substrate and an orthographic projection of the second gate on the substrate;
the orthographic projection of the power line on the substrate covers at least a portion of an orthographic projection of the first active region on the substrate;
the orthographic projection of the power line on the substrate covers at least a portion of the orthographic projection of the first capacitor on the substrate.

12. The array substrate according to claim 11, wherein the at least two scan lines comprise a fourth scan line, the fourth scan line comprises a third sub-line located in the first conductive layer, a fourth sub-line located in the third conductive layer, and a fifth sub-line located in the fourth conductive layer, and the third sub-line, the fourth sub-line, and the fifth sub-line are connected via vias;
an orthographic projection of the fourth scan line on the substrate overlaps with an orthographic projection of a channel region of a second light emission control transistor in a pixel circuit of an m-th row on the substrate, wherein m is a positive integer, and pixel circuits in each row are arranged along the first direction;
the orthographic projection of the fourth scan line on the substrate overlaps with an orthographic projection of a channel region of the first reset transistor in a pixel circuit of an (m+1)-th row on the substrate;
the at least two scan lines further comprise a third scan line, the third scan line is configured to drive a second reset transistor of the pixel circuit, the first scan line is located on a side of the third scan line close to the driving transistor, and the second scan line is located on a side of the fourth scan line close to the driving transistor;
a portion of the fourth scan line is reused as a gate of the second light emission control transistor and a gate of the first reset transistor.

13. The array substrate according to claim 12, wherein the fourth conductive layer further comprises a first reset signal line and a second reset signal line extending along the first direction; in a same pixel circuit located in the m-th row, orthographic projections of a first light emission control transistor, the second reset transistor, the first capacitor, the second capacitor, and the driving transistor on the substrate are located between an orthographic projection of the first reset signal line corresponding to a pixel circuit of the (m+1)-th row on the substrate and an orthographic projection of the second reset signal line corresponding to the pixel circuit of the m-th row on the substrate; wherein m is a positive integer, and pixel circuits in each row are arranged along the first direction;
in the second direction, an orthographic projection of the first reset signal line on the substrate is located on a side of an orthographic projection of the fourth scan line on the substrate close to an orthographic projection of the driving transistor on the substrate, and the second scan line is located on a side of the first reset signal line close to the driving transistor;
an orthographic projection of the first electrode plate on the substrate, the orthographic projection of the first reset signal line on the substrate, and the orthographic projection of the fourth scan line on the substrate are sequentially arranged along the second direction.

14. The array substrate according to claim 3, wherein the pixel circuit further comprises a second light emission control transistor and a first reset transistor;
the second active layer comprises a fourth active region, and a channel region of the second light emission control transistor is located in the fourth active region; the first active layer comprises a fifth active region, and a channel region of the first reset transistor is located in the fifth active region;
in the second direction, orthographic projections of the fourth active region and the fifth active region in a same pixel circuit on the substrate are located on the same side of the orthographic projection of the first capacitor on the substrate away from an orthographic projection of the second capacitor on the substrate;
in the first direction, orthographic projections of the fourth active region and the fifth active region in the same pixel circuit on the substrate are sequentially arranged; both the fourth active region and the fifth active region extend along the second direction.

15. The array substrate according to claim 14, wherein the at least two scan lines comprise a first scan line, a second scan line and a fourth scan line, the fourth scan line comprising a third sub-line located in the first conductive layer, a fourth sub-line located in the third conductive layer, and a fifth sub-line located in the fourth conductive layer;
an orthographic projection of the fourth scan line on the substrate overlaps with orthographic projections of a channel region of the second light emission control transistor and a channel region of the first reset transistor in a pixel circuit of an m-th row on the substrate;
wherein m is a positive integer, and pixel circuits of each row are arranged along the first direction;
the fourth conductive layer further comprises a first reset signal line and a second reset signal line extending along the first direction; the pixel circuit further comprises a first light emission control transistor and a second reset transistor;
within a same pixel circuit, orthographic projections of the first light emission control transistor, the second reset transistor, a first capacitor, a second capacitor, and the driving transistor on the substrate are located between orthographic projections of the first reset signal line and the second reset signal line on the substrate;
in the second direction perpendicular to the first direction, an orthographic projection of the first reset signal line is located on a side of the orthographic projection of the fourth scan line on the substrate opposite to the driving transistor.

16. An array substrate, comprising:
a substrate;
a first conductive layer, a third conductive layer, and a fourth conductive layer sequentially stacked along a direction away from the substrate;
a first scan line, located in the fourth conductive layer;
a third scan line, located in the first conductive layer and the fourth conductive layer;
a fourth scan line, located in the first conductive layer, the third conductive layer, and the fourth conductive layer;
wherein orthographic projections of the first scan line, the third scan line, and the fourth scan line on the substrate all extend along a first direction and are spaced apart along a second direction, the first direction intersects with the second direction.

17. The array substrate according to claim 16, further comprising: at leat one active layer disposed on one side of the substrate in a stacked manner, the at leat one active layer, the a first conductive layer, the third conductive layer, and the fourth conductive layer forming at least one pixel circuit, the pixel circuit comprising a first capacitor, a second capacitor, a driving transistor, and a plurality of switching transistors;
the array substrate further comprising: a second scan line located in a second conductive layer, the second conductive layer being located on a side of the first conductive layer away from the substrate;
along the second direction, an orthographic projection of the first capacitor on the substrate, an orthographic projection of the second capacitor on the substrate, and an orthographic projection of the driving transistor on the substrate are located between an orthographic projection of the first scan line on the substrate and an orthographic projection of the second scan line on the substrate;
the plurality of switching transistors comprise a data write transistor, a threshold compensation transistor, a first light emission control transistor, a second light emission control transistor, a first reset transistor, and a second reset transistor, the first scan line being connected to a gate of the data write transistor, the second scan line being connected to a gate of the threshold compensation transistor, the third scan line being connected to a gate of the first reset transistor and a gate of the second light emission control transistor, the fourth scan line being connected to a gate of the second reset transistor and a gate of the first light emission control transistor; the first scan line is located on a side of the third scan line closer to the driving transistor, and the second scan line is located on a side of the fourth scan line closer to the driving transistor;
an orthographic projection of the first capacitor on the substrate overlaps with an orthographic projection of the driving transistor on the substrate; an orthographic projection of the first capacitor on the substrate and an orthographic projection of the second capacitor on the substrate are spaced apart.

18. The array substrate according to claim 17, wherein the at leat one active layer comprises a first active layer and a second active layer, the second active layer is located on one side of the substrate, the first conductive layer is located on a side of the second active layer away from the substrate, the second conductive layer is located on a side of the first conductive layer away from the substrate, the first active layer is located on a side of the second conductive layer away from the substrate, the third conductive layer is located on a side of the first active layer away from the substrate;
the first active layer comprises a first active region, and the second active layer comprises a second active region, a channel region of the data write transistor is located in the second active region, and a gate of the data write transistor is located in the first conductive layer, the gate of the data write transistor extends along the second direction, a first electrode of the data write transistor, the channel region of the data write transistor, and a second electrode of the data write transistor are sequentially arranged along the first direction;
a gate of the threshold compensation transistor is at least located in the third conductive layer, and the gate of the threshold compensation transistor extends along the first direction, a channel region of the threshold compensation transistor is located in the first active region; a first gate of the driving transistor is located in the second conductive layer, a second gate of the driving transistor is located in the third conductive layer, and a channel region of the driving transistor is located in the first active region; a second plate is reused as the first gate; an orthographic projection of a first plate on the substrate covers an orthographic projection of the second plate on the substrate; an orthographic projection of the first gate on the substrate covers an orthographic projection of the second gate on the substrate.

19. The array substrate according to claim 18, wherein the first active region comprises a first active portion, a second active portion, a third active portion, and a fourth active portion connected in sequence; the first active portion and the third active portion extend along the first direction, and the second active portion and the fourth active portion extend along the second direction;
the first active portion comprises a channel region of the driving transistor, and the fourth active portion comprises a channel region of the threshold compensation transistor, an orthographic projection of the third gate on the substrate overlaps with an orthographic projection of the fourth active portion on the substrate;
the orthographic projection of the third gate on the substrate is spaced apart from an orthographic projection of the second active portion on the substrate;
a first boundary of the orthographic projection of the third gate on the substrate, the orthographic projection of the fourth active portion on the substrate, a second boundary of the orthographic projection of the third gate on the substrate, and the orthographic projection of the second active portion on the substrate are sequentially arranged along the first direction.

20. A display panel, comprising a array substrate, the array substrate comprising:
a substrate;
at leat one active layer and a plurality of conductive layers stacked on one side of the substrate, the at leat one active layer and the plurality of conductive layers forming at least one pixel circuit, the pixel circuit comprising a first capacitor, a second capacitor, a driving transistor and a plurality of switching transistors;
wherein the plurality of conductive layers comprises at least two scan lines, the scan lines extending along a first direction, the driving transistor and the plurality of switching transistors being each connected to one of the scan lines;
the plurality of switching transistors comprise a first-type transistor and a second-type transistor; along a second direction, an orthographic projection of the first capacitor on the substrate, an orthographic projection of the second capacitor on the substrate, and an orthographic projection of the driving transistor on the substrate are located between orthographic projections on the substrate of any two of the scan lines, the two scan lines being respectively connected to the first-type transistor and the second-type transistor, and the first capacitor and the second capacitor are arranged along the second direction, and the second direction intersects the first direction.
